(19) United States
(12) Patent Application Publication
(10) Pub. No.: US 2023/0121348 A1
(43) Pub. Date: Apr. 20, 2023

(54) APPARATUS AND METHOD FOR MANUFACTURING DISPLAY APPARATUS

(71) Applicant: Samsung Display Co., Ltd., Yongin-si (KR)

(72) Inventors: Kanguk KIM, Yongin-si (KR); Seonuk LEE, Yongin-si (KR); Donchan CHO, Yongin-si (KR)

(73) Assignee: Samsung Display Co., Ltd., Yongin-si (KR)

(21) Appl. No.: 17/965,029

(22) Filed: Oct. 13, 2022

(30) Foreign Application Priority Data
Oct. 14, 2021 (KR) 10-2021-0136891

(51) Int. Cl. H01L 51/56; H01L 51/52; H01L 27/32

(52) U.S. Cl. CPC H01L 51/56; H01L 51/5237; H01L 27/322; H01L 2251/303

(57) ABSTRACT

An apparatus for manufacturing a display apparatus includes a stage on which a substrate is disposed, a first driver that moves the stage in a first direction, a second driver connected to the first driver and moving the first driver in a second direction, and a discharge part facing the stage and supplying droplets to the substrate. The second driver moves the stage by a multiple of a natural number of 1 or more of a distance between pixels arranged on the substrate.

### CROSS-REFERENCE TO RELATED APPLICATION(S)

This application claims priority to and benefit of Korean Patent Application No. 10-2021-0136891 under 35 U.S.C. § 119, filed in the Korean Intellectual Property Office on Oct. 14, 2021, the entire contents of which are incorporated herein by reference.

### BACKGROUND

### 1. Technical Field

One or more embodiments relate to an apparatus and method for manufacturing a display apparatus without a defect such as a stripe.

### 2. Description of the Related Art

Electronic devices have grown in popularity because of the mobility thereof. Tablet personal computers (PCs), small-sized electronic devices such as mobile phones, or the like have been widely used as mobile electronic devices.

The mobile electronic devices include a display part for providing a user with visual information such as images or videos and support various functions. The display parts have grown in popularity in electronic devices because of the miniaturization of components for driving the display parts. Moreover, a display part having a curved structure at an angle from a flat state has been developed.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

In general, in case that a droplet is supplied to correspond to a pixel, a stripe or the like may be visually recognized on a substrate after all droplets are disposed on the substrate according to the concentration of a material included in the droplet.

Embodiments provide an apparatus for manufacturing a display apparatus, on which a defect such as a stripe is not visible.

Embodiments also provide a method for manufacturing a display apparatus, in which a defect such as a stripe is not visually recognized on a substrate.

However, embodiments of the disclosure are not limited to those set forth herein. The above and other embodiments will become more apparent to one of ordinary skill in the art to which the disclosure pertains by referencing the detailed description of the disclosure given below.

According to one or more embodiments, an apparatus for manufacturing a display apparatus includes a stage on which a substrate is disposed, a first driver that moves the stage in a first direction, a second driver connected to the first driver and moving the first driver in a second direction, and a discharge part facing the stage and supplying droplets to the substrate. The second driver may move the stage by a multiple of a natural number of 1 or more of a distance between pixels arranged on the substrate.

The second driver may move the substrate in the second direction such that the discharge part faces different regions of the substrate.

The substrate may include a plurality of coating regions. A distance between the plurality of coating regions may be a multiple of a natural number of 1 or more of the distance between the pixels arranged on the substrate. At least one of the first driver and the second driver may move the stage by the distance between the plurality of coating regions so as to make the discharge part correspond to adjacent ones of the plurality of coating regions.

The plurality of coating regions may be spaced apart from one another in the first direction and the second direction. A first distance between the plurality of coating regions spaced apart from each other in the first direction and a second distance between the plurality of coating regions spaced apart from each other in the second direction may each be multiples of a natural number of 1 or more of the distance between the pixels arranged on the substrate.

The droplets may include quantum dots.

The droplets may include a scatterer.

The droplets may include titanium oxide.

According to one or more embodiments, a method of manufacturing a display apparatus includes moving a substrate in a first direction and supplying droplets onto the substrate by a discharge part, moving the substrate in a second direction, and moving the substrate in an opposite direction to the first direction and supplying droplets onto the substrate by the discharge part. A distance by which the substrate moves in the second direction may be a multiple of a natural number of 1 or more of a distance between pixels arranged on the substrate.

The distance between the pixels on the substrate may be a distance between pixels that emit light of a same color and are adjacent to each other.

The droplets may include quantum dots.

The droplets may include a scatterer.

The droplets may include titanium oxide.

The method may further include forming a color filter layer on the substrate.

The method may further include forming a thin-film encapsulation layer on the substrate.

The method may further include arranging the substrate on a light-emitting panel.

The substrate may include a plurality of coating regions. A distance between the plurality of coating regions may be a multiple of a natural number of 1 or more of the distance between the pixels arranged on the substrate.

The method may further include moving the substrate by the multiple of the natural number of 1 or more of the distance between the pixels arranged on the substrate in the first direction such that the discharge part corresponds to one of the plurality of coating regions and another of the plurality of coating regions adjacent to the one of the plurality of coating regions in the first direction.

The method may further include moving the substrate by the multiple of the natural number of 1 or more of the distance between the pixels arranged on the substrate in the second direction such that the discharge part corresponds to one of the plurality of coating regions and another of the plurality of coating regions adjacent to the one of the plurality of coating regions in the second direction.

A size of a planar shape of one of the plurality of coating regions may be different from a size of a planar shape of another of the plurality of coating regions.

The discharge part may include a plurality of nozzles. In case that the droplets are supplied to an entire surface of the substrate, only some of the plurality of nozzles may continuously discharge the droplets.

These and/or other aspects will become apparent and more readily appreciated from the following description of the embodiments, taken in conjunction with the accompanying drawings.

These general and specific embodiments may be implemented by using a system, a method, a computer program, or a combination thereof.

### BRIEF DESCRIPTION OF THE DRAWINGS

An additional appreciation according to the embodiments of the disclosure will become more apparent by describing in detail the embodiments thereof with reference to the accompanying drawings, wherein:

FIG. 1 is a schematic perspective view of a display apparatus according to an embodiment;

FIG. 2 is a schematic cross-sectional view of a display apparatus according to an embodiment;

FIG. 3 is a schematic cross-sectional view of respective portions of a first quantum dot layer, a second quantum dot layer, and a light-transmissive layer of FIG. 2;

FIG. 4 is a schematic cross-sectional view of a display apparatus according to an embodiment;

FIG. 5 is a schematic plan view of a display apparatus according to an embodiment;

FIG. 6 is a schematic cross-sectional view of a display apparatus according to an embodiment;

FIG. 7 is a schematic perspective view of an apparatus for manufacturing a display apparatus, according to an embodiment;

FIGS. 8A to 8F are schematic plan views illustrating a method of manufacturing a display apparatus, according to an embodiment;

FIGS. 9A and 9B are schematic plan views of a color panel of a display apparatus according to an embodiment;

FIG. 10 is a schematic plan view of a color panel of a display apparatus according to an embodiment; and

FIG. 11 is a schematic plan view of a color panel of a display apparatus according to an embodiment.

### DETAILED DESCRIPTION OF THE EMBODIMENTS

Various embodiments are described herein with reference to sectional and/or exploded illustrations of the embodiments and/or intermediate structures. As such, variations from the shapes of illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

In the following description, for the purposes of explanation, numerous specific details are set forth in order to provide a thorough understand of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified or implied herein, the illustrated embodiments are to be understood as providing exemplary features of the disclosure. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the disclosure.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Although the terms “first,” “second,” and the like may be used herein to describe various types of elements, these elements should not be limited by these terms. These terms are used to distinguish one element from another element. Thus, a first element discussed below could be termed a second element without departing from the teachings of the disclosure.

The terminology used herein is for the purpose of describing particular embodiments and is not intended to be limiting. As used herein, the singular forms “a,” “an,” and “the” are intended to include the plural forms as well, unless the context clearly indicates otherwise.

Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

When an element, such as a layer, is referred to as being “on,” “connected to,” “coupled to,” or “formed on” another element or layer, it may be directly on, connected to, or coupled to the other element or layer or intervening elements may be present. When, however, an element or layer is referred to as being “directly on,” “directly connected to,” or “directly coupled to” another element of layer, there are no intervening elements or layers present. To this end, the term “connected” may refer to physical, electrical, and/or fluid connection, with or without intervening elements.

Further, in the accompanying drawings, the size and relative sizes of elements may be exaggerated for clarity and/or descriptive purpose. For example, since sizes and thicknesses of components in the drawings are arbitrarily illustrated for convenience of explanation, embodiments of the disclosure are not limited thereto.

Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another. The phrase “at least one of” is intended to include the meaning of “at least one selected from the group of” for the purpose of its meaning and interpretation. For example, “at least one of A and B” may be understood to mean “A, B, or A and B.”

When an embodiment may be implemented differently, a specific process order may be performed differently from the described order. For example, two consecutively described processes may be performed substantially at the same time or performed in an order opposite to the described order.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or”.

In the specifications and the claims, the meaning that a wire extends in a first direction or a second direction encompasses not only extending in a straight line but also extending in zigzags or in a curve in the first direction or the second direction. Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

In the specifications and the claims, when referred to “planar”, it means when an object is viewed from above, and when referred to “sectional”, it means when a cross section formed by vertically cutting an object is viewed from the side. In the following embodiments, when referred to “overlapping”, it encompasses “planar” overlapping and “cross-sectional” overlapping. As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some exemplary embodiments may be physically separated into two or more interacting and discrete blocks, units, and/or modules without departing from the scope of the disclosure. Further, the blocks, units, and/or modules of some exemplary embodiments may be physically combined into more complex blocks, units, and/or modules without departing from the scope of the disclosure.

One or more embodiments of the disclosure will be described below in more detail with reference to the accompanying drawings. Those components that are the same or are in correspondence are rendered the same reference numeral regardless of the figure number. Also, like reference numerals denote like elements.

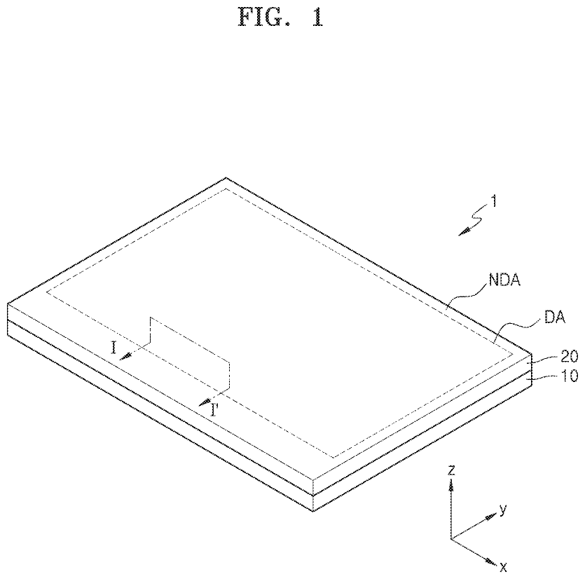

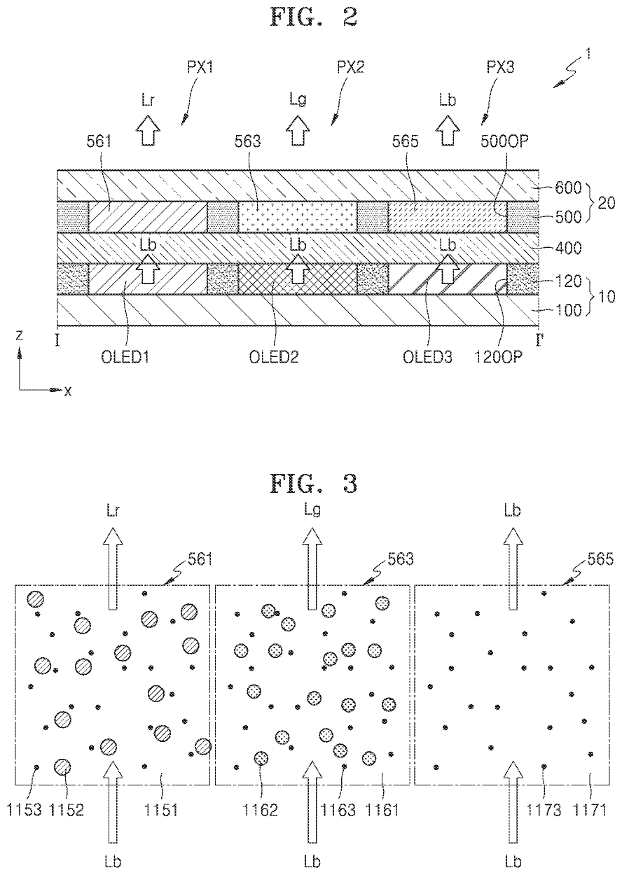

FIG. 1 is a schematic perspective view of a display apparatus 1 according to an embodiment, FIG. 2 is a schematic cross-sectional view of the display apparatus 1 according to an embodiment, and FIG. 3 is a schematic cross-sectional view of respective portions of a first quantum dot layer 561, a second quantum dot layer 563, and a light-transmissive layer 565 of FIG. 2. FIG. 2 is a schematic cross-sectional view of the display apparatus 1 taken along line I-I′ of FIG. 1.

Referring to FIG. 1, the display apparatus 1 may include a display area DA, and a non-display area NDA surrounding the display area DA. The display apparatus 1 may provide an image through an array of pixels arranged in a two-dimensional (2D) manner.

Each of the pixels included in the display apparatus 1 may be an area capable of emitting light of a color, and the display apparatus 1 may provide an image by using light emitted from the pixels. For example, each pixel may emit red light, green light, or blue light.

The non-display area NDA may not provide an image, and may surround (e.g., entirely surround) the display area DA. At least one driver line or at least one main power line may be arranged in the non-display area NDA. The driver line may provide an electrical signal. The main power line may provide a power to pixel circuits. The non-display area NDA may include a pad (or area) where an electronic device or a printed circuit board (PCB) may be electrically connected.

The display area DA may have a polygonal shape including a quadrangle, as shown in FIG. 1. For example, the display area DA may have a rectangular shape having a horizontal length greater than a vertical length. In other embodiments, the display area DA may have a rectangular shape having a horizontal length less than a vertical length, or a square shape. As another example, the display area DA may have any of various shapes such as an oval or a circle.

According to an embodiment, the display apparatus 1 may include a light-emitting panel 10 and a color panel 20 stacked in a thickness direction (e.g., a z direction). Referring to FIG. 2, the light-emitting panel 10 may include first to third light-emitting devices OLED1, OLED2, and OLED3 on a lower substrate 100. The first to third light-emitting devices OLED1, OLED2, and OLED3 may be organic light-emitting diodes.

Light emitted by the first to third light-emitting devices OLED1, OLED2, and OLED3 (for example, blue light Lb) may pass through the color panel 20, and be converted to or transmitted as red light Lr, green light Lg, and the blue light Lb.

According to an embodiment, a pixel defining layer 120 may be arranged on the lower substrate 100, and define respective emission regions (which may be referred to as emission areas) of the first to third light-emitting devices OLED1, OLED2, and OLED3. For example, the pixel defining layer 120 may include openings 120OP corresponding to the respective emission regions of the first to third light-emitting devices OLED1, OLED2, and OLED3.

According to an embodiment, the pixel defining layer 120 may include an organic insulating material. According to another embodiment, the pixel defining layer 120 may include an inorganic insulating material, such as silicon nitride (SiNₓ), silicon oxynitride (SiOₓN_{y}), or silicon oxide (SiOₓ). According to another embodiment, the pixel defining layer 120 may include an organic insulating material and an inorganic insulating material. According to an embodiment, the pixel defining layer 120 may include a light shielding material (or light blocking material), and may have a black color. The light shielding material (or light blocking material) may include carbon black, carbon nanotubes, resin or paste including a black pigment, metal (e.g., nickel, aluminum, molybdenum, and an alloy thereof) particles, metal oxide (e.g., a chromium oxide) particles, or metal nitride (e.g., a chromium nitride) particles. In case that the pixel defining layer 120 includes the light shielding material (or light blocking material), reflection of external light due to metal structures arranged under the pixel defining layer 120 may be reduced.

Although not shown in the drawings, a spacer may be arranged on the pixel defining layer 120. The spacer may include an organic insulating material such as polyimide. As another example, the spacer may include an inorganic insulating material such as silicon nitride (SiNₓ) or silicon oxide (SiOₓ), or may include an organic insulating material and an inorganic insulating material.

According to an embodiment, the spacer and the pixel defining layer 120 may include a same material. The pixel defining layer 120 and the spacer may be simultaneously (or concurrently) formed during a mask process that uses a half-tone mask. According to an embodiment, the spacer and the pixel defining layer 120 may include different materials from each other.

According to an embodiment, a filler 400 may be between the lower substrate 100 and an upper substrate 600. The filler 400 may function as a buffer against external pressure, or the like. The filler 400 may include an organic material such as methyl silicone, phenyl silicone, or polyimide. However, embodiments are not limited thereto, and the filler 400 may include an organic sealant such as a urethane-based resin, an epoxy-based resin, or an acrylic resin, or an inorganic sealant such as silicon.

According to an embodiment, a bank 500 may be arranged on the filler 400. The bank 500 may include various materials capable of absorbing light. The bank 500 and the pixel defining layer 120 may include a same material or may include different materials. For example, the bank 500 may include an opaque inorganic insulating material such as chromium oxide or molybdenum oxide, or an opaque organic insulating material such as black resin.

According to an embodiment, the bank 500 may include openings 5000O corresponding to the respective emission regions of the first to third light-emitting devices OLED1, OLED2, and OLED3. For example, the openings 500OP defined in the bank 500 may correspond to the openings 120OP defined in the pixel defining layer 120, respectively. According to an embodiment, a first quantum dot layer 561, a second quantum dot layer 563, and a light-transmissive layer 565 may be arranged in the openings 500OP defined in the bank 500, respectively.

Referring to FIGS. 2 and 3, the first quantum dot layer 561 may convert blue light Lb incident thereto to the red light Lr. The first quantum dot layer 561 may include first quantum dots 1152, first scatterers 1153, and a first photosensitive polymer 1151. The first quantum dots 1152 and the first scatterers 1153 may be dispersed in the first photosensitive polymer 1151.

The first quantum dots 1152 may be excited by the blue light Lb and isotropically emit the red light Lr having a longer wavelength than a wavelength of the blue light Lb. The first photosensitive polymer 1151 may be an organic material having a light-transmitting property. The first scatterers 1153 may scatter the blue light Lb not absorbed by the first quantum dots 1152 and increase color conversion efficiency. Thus, more first quantum dots 1152 may be excited. The first scatterers 1153 may be, for example, titanium oxide (TiO₂) or metal particles. The first quantum dots 1152 may be selected from a group including a Group II-VI elements-containing compound, a Group III-V elements-containing compound, a Group IV-VI elements-containing compound, a Group IV element, a Group IV element-containing compound, and a combination thereof.

According to an embodiment, the first quantum dot layer 561 may convert light of a third wavelength band into light of a first wavelength band. For example, in case that light having a wavelength in a range of about 450 nm to about 495 nm is generated by the first light-emitting device OLED1, the first quantum dot layer 561 may convert the generated light into light Lr having a wavelength in a range of about 630 nm to about 780 nm. Accordingly, in a first pixel PX1, the red light Lr having the wavelength in a range of about 630 nm to about 780 nm may be emitted to the outside through the upper substrate 600.

According to an embodiment, the second quantum dot layer 563 may include second quantum dots 1162, second scatterers 1163, and a second photosensitive polymer 1161. The second quantum dots 1162 and the second scatterers 1163 may be dispersed in the second photosensitive polymer 1161. The second quantum dots 1162 may be excited by the blue light Lb and isotropically emit the green light Lg having a longer wavelength than the wavelength of the blue light Lb. The second photosensitive polymer 1161 may be an organic material having a light-transmitting property. The second scatterers 1163 may scatter the blue light Lb not absorbed by the second quantum dots 1162, and increase color conversion efficiency. Thus, more second quantum dots 1162 may be excited. The second scatterers 1163 may be, for example, titanium oxide (TiO₂) or metal particles. The second quantum dots 1162 may be selected from a group including a Group II-VI elements-containing compound, a Group III-V elements-containing compound, a Group IV-VI elements-containing compound, a Group IV element, a Group IV element-containing compound, and a combination thereof. According to an embodiment, the first quantum dots 1152 and the second quantum dots 1162 may include a same material, and a size of the second quantum dots 1162 may be less than that of the first quantum dots 1152.

According to an embodiment, the second quantum dot layer 563 may convert the light of the third wavelength band into light of a second wavelength band. For example, in case that light having a wavelength in a range of about 450 nm to about 495 nm is generated by the second light-emitting device OLED2, the second quantum dot layer 563 may convert the generated light into light Lg (e.g., green light Lg) having a wavelength in a range of about 495 nm to about 570 nm. Accordingly, in a second pixel PX2, light Lg having the wavelength in a range of about 495 nm to about 570 nm may be emitted to the outside through the upper substrate 600.

The light-transmissive layer 565 may transmit the blue light Lb. The light-transmissive layer 565 may include third scatterers 1173 and a third photosensitive polymer 1171. The third scatterers 1173 may be dispersed in the third photosensitive polymer 1171. The third photosensitive polymer 1171 may be, for example, an organic material having a light transmitting property, such as silicon resin or epoxy resin. The first to third photosensitive polymers 1151, 1161, and 1171 may include a same material. The third scatterers 1173 may scatter and emit the blue light Lb. The first to third scatterers 1153, 1163, and 1173 may include a same material.

According to an embodiment, the first quantum dot layer 561, the second quantum dot layer 563, and the light-transmissive layer 565 may be formed within the openings 500OP of the bank 500 via inkjet printing, respectively.

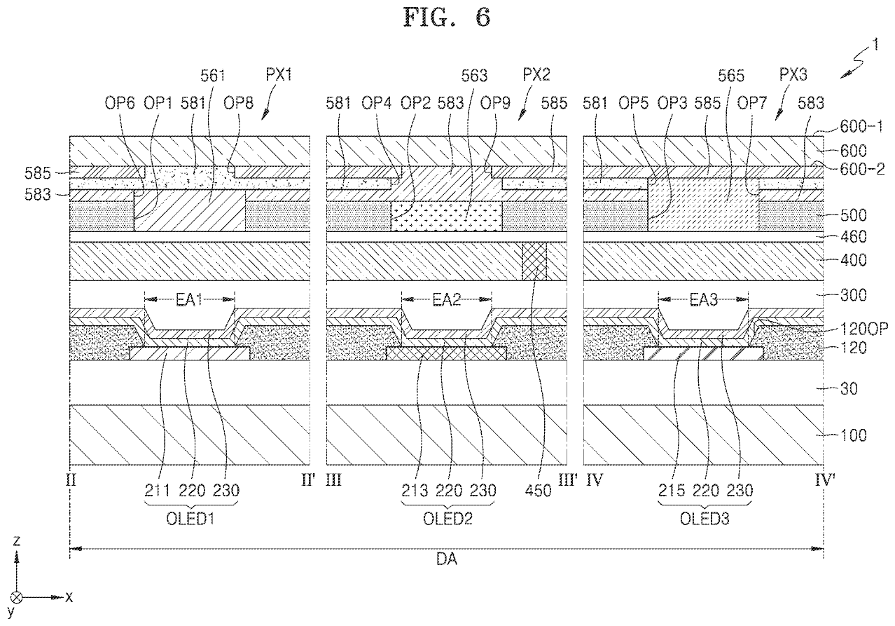

According to an embodiment, the upper substrate 600 may be arranged on the first quantum dot layer 561, the second quantum dot layer 563, and the light-transmissive layer 565. A first color filter layer 581 of FIG. 6 may be arranged between the first quantum dot layer 561 and the upper substrate 600, a second color filter layer 583 of FIG. 6 may be arranged between the second quantum dot layer 563 and the upper substrate 600, and a third color filter layer 585 of FIG. 6 may be arranged between the light-transmissive layer 565 and the upper substrate 600. Description of the first to third color filter layers 581, 583, and 585 is provided below with reference to FIG. 6.

Each of the lower substrate 100 and the upper substrate 600 may include at least one of glass, metal, and polymer resin. In case that the lower substrate 100 and the upper substrate 600 are flexible or bendable, the lower substrate 100 and the upper substrate 600 may each include polymer resin such as polyethersulfone, polyacrylate, polyetherimide, polyethylene naphthalate, polyethylene terephthalate, polyphenylene sulfide, polyarylate, polyimide, polycarbonate, or cellulose acetate propionate. The lower substrate 100 and the upper substrate 600 may each have a multi-layered structure including two layers each including a polymer resin as mentioned above and a barrier layer including an inorganic material, such as silicon nitride (SiNₓ), silicon oxynitride (SiOₓN_{y}), or silicon oxide (SiOₓ), between the two layers. In this way, various modifications may be made.

According to an embodiment, the display apparatus 1 may be formed by forming the first, second, and third light-emitting devices OLED1, OLED2, and OLED3 on the lower substrate 100, forming the first and second quantum dot layers 561 and 563 and the light-transmissive layer 565 on the upper substrate 600, and coupling the lower substrate 100 including the first, second, and third light-emitting devices OLED1, OLED2, and OLED3 formed thereon with the upper substrate 600 including the first and second quantum dot layers 561 and 563 and the light-transmissive layer 565 formed thereon.

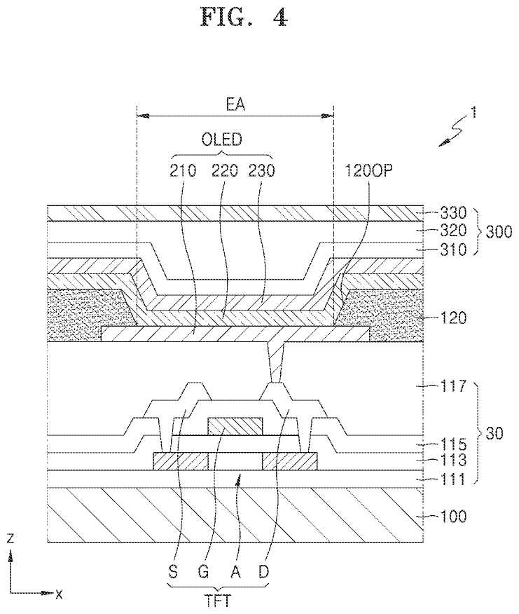

FIG. 4 is a schematic cross-sectional view of the display apparatus 1 according to an embodiment.

Referring to FIG. 4, the display apparatus 1 may further include a thin-film transistor TFT, a light-emitting device OLED, and a thin-film encapsulation layer 300. The thin-film transistor TFT, the light-emitting device OLED, and the thin-film encapsulation layer 300 may be arranged on the lower substrate 100. A buffer layer 111 may be arranged on the lower substrate 100. The buffer layer 111 may include an inorganic material, such as silicon nitride (SiNₓ), silicon oxynitride (SiOₓN_{y}), or silicon oxide (SiOₓ). The buffer layer 111 may be arranged on the lower substrate 100 and increase smoothness of (or planarize) an upper surface of the lower substrate 100. For example, the buffer layer 111 may prevent (or minimize) infiltration of impurities from the lower substrate 100 (or other elements) into a semiconductor layer A of the thin-film transistor TFT.

The thin-film transistor TFT may be arranged on the buffer layer 111. The thin-film transistor TFT may include the semiconductor layer A, a gate electrode G, a source electrode S, and a drain electrode D. The semiconductor layer A may be arranged on the buffer layer 111. The semiconductor layer A may include at least one of amorphous silicon, polycrystalline silicon, an organic semiconductor material, and an oxide semiconductor material.

A first insulating layer 113 may be arranged on the semiconductor layer A. The first insulating layer 113 may include an inorganic material, such as silicon nitride (SiNₓ), silicon oxynitride (SiOₓN_{y}), or silicon oxide (SiOₓ), and may be a single layer or multiple layers including an inorganic material. The first insulating layer 113 may be between the semiconductor layer A and the gate electrode G, and secure insulation (e.g., electrical insulation) between the semiconductor layer A and the gate electrode G. For example, the first insulating layer 113 may electrically insulate the semiconductor layer A from the gate electrode G.

The gate electrode G may be arranged on the first insulating layer 113. The gate electrode GE may include a low-resistance conductive material such as molybdenum (Mo), aluminum (Al), copper (Cu), and titanium (Ti), and may have a multi-layer structure or a single layer structure including the aforementioned materials.

A second insulating layer 115 may be arranged on the gate electrode G. The second insulating layer 115 may include an inorganic material, such as silicon nitride (SiNₓ), silicon oxynitride (SiOₓN_{y}), and silicon oxide (SiOₓ), and may be a single layer or multiple layers including the inorganic material.

The source electrode S and the drain electrode D may be arranged on the second insulating layer 115. The source electrode S and the drain electrode D may include at least one material selected from a group including copper, titanium, and aluminum. For example, each of the source electrode S and the drain electrode D may have a three-layered structure of Ti layer/Al layer/Ti layer.

A planarization layer 117 may be arranged on the source electrode S and the drain electrode D. The planarization layer 117 may be a single-layered polyimide-based resin layer. However, embodiments are not limited thereto. The planarization layer 117 may include at least one of acrylic resin, methacryl resin, polyisoprene, vinyl-based resin, epoxy-based resin, urethane-based resin, cellulose-based resin, siloxane-based resin, polyamide-based resin, and perylene-based resin.

The light-emitting device OLED may be arranged on the planarization layer 117. The light-emitting device OLED may include a pixel electrode 210, an intermediate layer 220, and an opposite electrode 230. The pixel electrode 210 may be arranged on the planarization layer 117. The pixel electrode 210 may be electrically connected to the source electrode S and/or the drain electrode D through a via hole passing through the planarization layer 117. Accordingly, the light-emitting device OLED may be electrically connected to the thin-film transistor TFT.

The pixel electrode 210 may include conductive oxide such as indium tin oxide (ITO), indium zinc oxide (IZO), zinc oxide (ZnO), indium oxide (In₂O₃), indium gallium oxide (IGO), or aluminum zinc oxide (AZO). According to an embodiment, the pixel electrode 210 may include a reflective layer including at least one of silver (Ag), magnesium (Mg), aluminum (Al), platinum (Pt), palladium (Pd), gold (Au), nickel (Ni), neodymium (Nd), iridium (Ir), and chromium (Cr). For example, the pixel electrode 210 may include an alloy of the above-described materials. According to an embodiment, the pixel electrode 210 may further include a film formed of (or including) ITO, IZO, ZnO, or In₂O₃ over/under the reflective layer. For example, the pixel electrode 210 may have a multi-layered structure of ITO/Ag/ITO.

A pixel defining layer 120 having an opening 120OP through which at least a portion of the pixel electrode 210 is exposed may be arranged on the pixel electrode 210. The opening 120OP defined in the pixel defining layer 120 may define an emission area EA of the light emitted by the light-emitting device OLED. For example, a width of the opening 120OP defined in the pixel defining layer 120 may correspond to a width of the emission area EA. An area around the emission area EA is a non-light emitting area, and the non-light emitting area may surround the emission area EA.

An intermediate layer 220 including an emission layer may be arranged on the pixel electrode 210. The intermediate layer 220 may include a low-molecular weight material or a high-molecular weight material. In case that the intermediate layer 220 includes a low-molecular weight material, the intermediate layer 220 may have a single-layered structure or a multi-layered stack structure including at least one of a hole injection layer (HIL), a hole transport layer (HTL), an emission layer (EML), an electron transport layer (ETL), and an electron injection layer (EIL), and may be formed via vacuum deposition. In case that the intermediate layer 220 includes a high-molecular weight material, the intermediate layer 220 may have a structure including an HTL and an EML. The HTL may include poly(ethylenedioxythiophene) (PEDOT), and the emission layer may include at least one high-molecular weight material such as a polyphenylene vinylene (PPV)-based material or a polyfluorene-based material. The intermediate layer 220 is not limited thereto, and may have any of various other structures. The intermediate layer 220 may be formed via screen printing, inkjet printing, deposition, laser induced thermal imaging (LITI), or the like.

According to an embodiment, the intermediate layer 220 may include the emission layer, and the emission layer may emit light of a third wavelength band. For example, the emission layer may emit light having a wavelength in a range of about 450 nm to about 495 nm. The emission layer may be integrally formed, and cover (or overlap, e.g., in a plan view) the entire lower substrate 100. However, embodiments are not limited thereto. The emission layer may, for each pixel, be patterned to correspond to the opening 120OP of the pixel defining layer 120.

An opposite electrode 230 may be arranged on the intermediate layer 220. The opposite electrode 230 may include a conductive material having a low work function. For example, the opposite electrode 230 may include a (semi)transparent layer including, for example, silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca) or an alloy of these materials. As another example, the opposite electrode 230 may further include a layer, such as ITO, IZO, ZnO, or In₂O₃, on the (semi)transparent layer including at least one of the above-described materials.

Although not shown in the drawings, a capping layer may be further arranged on the opposite electrode 230. The capping layer may include at least one of lithium fluoride (LiF), an inorganic material, and an organic material.

Because such a light-emitting device OLED may be readily damaged by external moisture, oxygen, or the like, an encapsulation layer may cover the light-emitting device OLED to protect the light-emitting device OLED. The encapsulation layer may be implemented as a thin-film encapsulation layer 300 including at least one inorganic encapsulation layer and at least one organic encapsulation layer. The thin-film encapsulation layer 300 may include a first inorganic layer 310, an organic layer 320, and a second inorganic layer 330 sequentially stacked one another.

The first inorganic layer 310 may be arranged (e.g., directly arranged) on the opposite electrode 230. The first inorganic layer 310 may prevent or minimize permeation of external moisture or oxygen into the light-emitting device OLED.

The organic layer 320 may be arranged (e.g., directly arranged) on the first inorganic layer 310. The organic layer 320 may planarize an upper surface of the first inorganic layer 310. Curves or particles formed on the upper surface of the first inorganic layer 310 may be covered by the organic layer 320, and prevent a surface state of the upper surface of the first inorganic layer 310 from affecting structures formed on the organic layer 320. For example, the organic layer 320 may cover a step difference (or height or thickness differences) formed by the curved structures or the particles on the first inorganic layer 310, and the structures formed on the organic layer 320 may not be affected by the step difference.

The second inorganic layer 330 may be arranged (e.g., directly arranged) on the organic layer 320. The second inorganic layer 330 may prevent or minimize outward permeation of moisture or the like emitted by the organic layer 320.

The first inorganic layer 310 and the second inorganic layer 330 may include at least one of a silicon oxide (SiOₓ), a silicon nitride (SiNₓ), a silicon oxynitride (SiOₓN_{y}), an aluminum oxide (Al₂O₃), a titanium oxide (TiO₂), a tantalum oxide (Ta₂O₅), a hafnium oxide (HfO₂), a zinc oxide (ZnOₓ), or the like. The zinc oxide (ZnOₓ) may be zinc oxide (ZnO) and/or zinc peroxide (ZnO₂). Each of the first inorganic layer 310 and the second inorganic layer 330 may have a single-layered structure or a multi-layered structure including the aforementioned materials. The organic layer 320 may include a polymer-based material. Examples of the polymer-based material may include at least one of an acrylic resin, an epoxy-based resin, polyimide, and polyethylene. According to an embodiment, the organic layer 320 may include acrylate.

According to an embodiment, the components between the lower substrate 100 and the pixel defining layer 120 may be collectively referred to as an insulating layer 30.

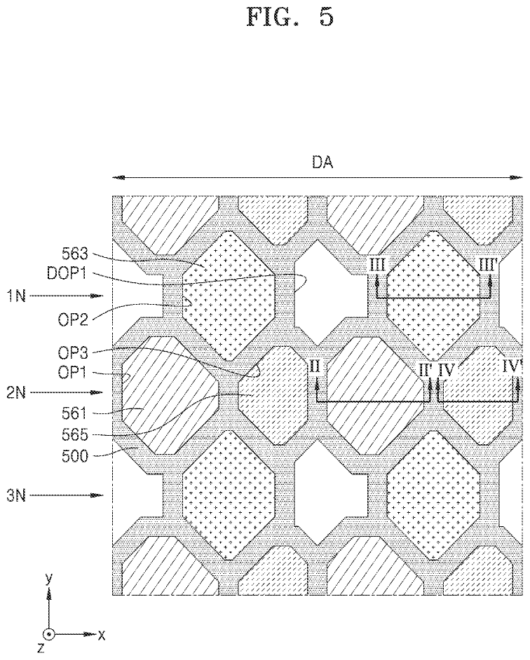

FIG. 5 is a schematic plan view of the display apparatus 1 according to an embodiment, and FIG. 6 is a schematic cross-sectional view of the display apparatus 1 according to an embodiment. For example, FIG. 5 is a schematic plan view of a portion of the display area DA (e.g., the emission area EA and the non-light emitting area), and FIG. 6 is a schematic cross-sectional view of the portion of the display area DA (e.g., the emission area EA and the non-light emitting area) taken along lines and IV-IV′ of FIG. 5.

Referring to FIGS. 5 and 6, the insulating layer 30 may be arranged on the lower substrate 100. As described above with reference to FIG. 4, the insulating layer 30 may include the buffer layer 111, the first insulating layer 113, the second insulating layer 115, and the planarization layer 117, and the thin-film transistor TFT may be arranged in the insulating layer 30.

A first pixel electrode 211, a second pixel electrode 213, and a third pixel electrode 215 may be arranged on the insulating layer 30. The pixel defining layer 120 may be arranged on the first, second, and third pixel electrodes 211, 213, and 215. The pixel defining layer 120 may include the openings 120OP exposing at least respective portions of the first, second, and third pixel electrodes 211, 213, and 215. The openings 120OP defined in the pixel defining layer 120 may define respective emission areas EA1, EA2, and EA3 (i.e., first to third emission areas EA1, EA2, and EA3) of pixels PX1, PX2, and PX3 (i.e., first to third pixels PX1, PX2, and PX3).

The first light-emitting device OLED1 may have the first emission area EA1, and the first emission area EA1 of the first light-emitting device OLED1 may be defined by the opening 120OP of the pixel defining layer 120. The first emission area EA1 may correspond to an area (e.g., emission area) of the light emitted by the first light-emitting device OLED1.

The second light-emitting device OLED2 may have the second emission area EA2, and the second emission area EA2 of the second light-emitting device OLED2 may be defined by the opening 120OP of the pixel defining layer 120. The second emission area EA2 may correspond to an area (e.g., emission area) of the light emitted by the second light-emitting device OLED2.

The third light-emitting device OLED3 may have the third emission area EA3, and the third emission area EA3 of the third light-emitting device OLED3 may be defined by the opening 120OP of the pixel defining layer 120. The third emission area EA3 may correspond to an area (e.g., emission area) of the light emitted by the third light-emitting device OLED3.

The pixel defining layer 120 may increase a distance between an edge of the first pixel electrode 211 and the opposite electrode 230, a distance between an edge of the second pixel electrode 213 and the opposite electrode 230, and a distance between an edge of the third pixel electrode 215 and the opposite electrode 230. Thus, the pixel defining layer 120 may prevent a defect (e.g., electric arc or the like) on the edges of the first, second, and third pixel electrodes 211, 213, and 215.

An intermediate layer 220 may be arranged on the first to third pixel electrodes 211, 213, and 215. The opposite electrode 230 may be arranged on the intermediate layer 220. The intermediate layer 220 may be integrally formed over the first, second, and third pixel electrodes 211, 213, and 215. However, embodiments are not limited thereto. The intermediate layer 220 may be formed on each of the first, second, and third pixel electrodes 211, 213, and 215, and patterned in correspondence with each of the first, second, and third pixel electrodes 211, 213, and 215.

The thin-film encapsulation layer 300 may be arranged on the first to third light-emitting devices OLED1, OLED2, and OLED3. As described above with reference to FIG. 4, the thin-film encapsulation layer 300 may include the first inorganic layer 310, the organic layer 320, and the second inorganic layer 330 sequentially stacked one another.

The upper substrate 600 may be positioned over the lower substrate 100. The first light-emitting device OLED1 including the first pixel electrode 211, the second light-emitting device OLED2 including the second pixel electrode 213, and the third light-emitting device OLED3 including the third pixel electrode 215 may be disposed between the upper substrate 600 and the lower substrate 100. The upper substrate 600 may include polymer resin. The upper substrate 600 may include polymer resin, such as polyethersulfone, polyacrylate, polyetherimide, polyethylene naphthalate, polyethylene terephthalate, polyphenylene sulfide, polyarylate, polyimide, polycarbonate, and cellulose acetate propionate. The upper substrate 600 may have a multi-layered structure including two layers each including the above-described polymer resin and a barrier layer disposed between the two layers. The barrier layer of the multi-layered structure may include an inorganic material, such as silicon nitride (SiNₓ), silicon oxynitride (SiOₓN_{y}), and silicon oxide (SiOₓ). Various modifications may be made. The upper substrate 600 may be flexible or bendable.

According to an embodiment, the upper substrate 600 may include an upper surface 600-1 and a lower surface 600-2. The lower surface 600-2 may refer to a surface that is closer to the lower substrate 100 than the upper surface 600-1 is.

According to an embodiment, the bank 500 may be between the lower substrate 100 and the upper substrate 600. The bank 500 may include various materials capable of absorbing light. The bank 500 may include first, second, and third openings OP1, OP2, and OP3 corresponding to the first, second, and third emission areas EA1, EA2, and EA3 of the first, second, and third light-emitting devices OLED1, OLED2, and OLED3. For example, the first opening OP1 corresponding to the first emission area EA1 of the first light-emitting device OLED1, the second opening OP2 corresponding to the second emission area EA2 of the second light-emitting device OLED2, and the third opening OP3 corresponding to the third emission area EA3 of the third light-emitting device OLED3 may be defined in the bank 500 arranged in the display area DA.

According to an embodiment, the first opening OP1, the second opening OP2, and the third opening OP3 defined in the bank 500 may correspond to the openings 120OP defined in the pixel defining layer 120, respectively. For example, the first opening OP1 defined in the bank 500 may correspond to the opening 120OP of the pixel defining layer 120 defining the first emission area EA1, the second opening OP2 defined in the bank 500 may correspond to the opening 120OP of the pixel defining layer 120 defining the second emission area EA2, and the third opening OP3 defined in the bank 500 may correspond to the opening 120OP of the pixel defining layer 120 defining the third emission area EA3. For example, the first to third openings OP1, OP2, and OP3 of the bank 500 corresponding to the openings 120OP of the pixel defining layer 120 defining the first to third emission areas EA1, EA2, and EA3, respectively, may refer to the shapes of respective edges of the first to third openings OP1, OP2, and OP3 of the bank 500 being the same as or similar to those of the openings 120OP of the pixel defining layer 120 defining the first to third emission areas EA1, EA2, and EA3, respectively, as viewed in a direction (e.g., z direction) perpendicular to the upper surface 600-1 of the upper substrate 600.

According to an embodiment, the areas of the first to third openings OP1, OP2, and OP3 defined in the bank 500 may be greater than those of the openings 120OP of the pixel defining layer 120 respectively defining the first to third emission areas EA1, EA2, and EA3.

According to an embodiment, the first quantum dot layer 561 may be arranged within the first opening OP1 defined in the bank 500. The second quantum dot layer 563 may be arranged within the second opening OP2 defined in the bank 500. The light-transmissive layer 565 may be arranged within the third opening OP3 defined in the bank 500. The first quantum dot layer 561, the second quantum dot layer 563, and the light-transmissive layer 565 may include the materials mentioned above with reference to FIG. 3.

According to an embodiment, the first quantum dot layer 561, the second quantum dot layer 563, and the light-transmissive layer 565 may be formed within the first opening OP1, the second opening OP2, and the third opening OP3 of the bank 500, respectively, via inkjet printing.

According to an embodiment, the first color filter layer 581, the second color filter layer 583, and the third color filter layer 585 may be arranged on the lower surface 600-2 of the upper substrate 600. The first color filter layer 581 may be arranged (e.g., directly arranged) on the first quantum dot layer 561. The second color filter layer 583 may be arranged (e.g., directly arranged) on the second quantum dot layer 563. The third color filter layer 585 may be arranged (e.g., directly arranged) on the light-transmissive layer 565. Accordingly, light converted by the first quantum dot layer 561 may be incident (e.g., directly incident) upon the first color filter layer 581. Light converted by the second quantum dot layer 563 may be incident (e.g., directly incident) upon the second color filter layer 583. Light transmitted through the light-transmissive layer 565 may be incident (e.g., directly incident) upon the third color filter layer 585.

According to an embodiment, the first color filter layer 581, the second color filter layer 583, and the third color filter layer 585 may transmit only light having different wavelength bands. For example, the first color filter layer 581 may transmit only light of the first wavelength band. The second color filter layer 583 may transmit only light of the second wavelength band. The third color filter layer 585 may transmit only light of the third wavelength band. The first wavelength band may be in a range of about 630 nm to about 780 nm. The second wavelength band may be in a range of about 495 nm to about 570 nm. The third wavelength band may be in a range of about 450 nm to about 495 nm. For example, the first color filter layer 581 may transmit only light of the first wavelength band in a range of about 630 nm to about 780 nm. The second color filter layer 583 may transmit only light having the second wavelength in a range of about 495 nm to about 570 nm. The third color filter layer 585 may transmit only light having the third wavelength in a range of about 450 nm to about 495 nm.

According to an embodiment, the first color filter layer 581 may overlap (or overlap at least a portion) the first light-emitting device OLED1 including the first pixel electrode 211 in a plan view. For example, the first color filter layer 581 may overlap (or overlap at least a portion) the first emission area EA1 of the first light-emitting device OLED1 in a plan view. Accordingly, the light emitted by the first light-emitting device OLED1 may pass through the first color filter layer 581. Description of the first color filter layer 581 is provided below.

According to an embodiment, the second color filter layer 583 may overlap (or overlap at least a portion) the second light-emitting device OLED2 including the second pixel electrode 213 in a plan view. For example, the second color filter layer 583 may overlap (or overlap at least a portion) the second emission area EA2 of the second light-emitting device OLED2 in a plan view. Accordingly, the light emitted by the second light-emitting device OLED2 may pass through the second color filter layer 583. Description of the second color filter layer 583 is provided below.

According to an embodiment, the third color filter layer 585 may overlap (or overlap at least a portion) the third light-emitting device OLED3 including the third pixel electrode 215 in a plan view. For example, the third color filter layer 585 may overlap (or overlap at least a portion) the third emission area EA3 of the third light-emitting device OLED3 in a plan view. Accordingly, the light emitted by the third light-emitting device OLED3 may pass through the third color filter layer 585. Description of the third color filter layer 585 is provided below.

According to an embodiment, a fourth opening OP4 and a fifth opening OP5 may be defined in the first color filter layer 581. The fourth opening OP4 defined in the first color filter layer 581 may overlap (or overlap at least a portion) the second color filter layer 583 in a plan view. The fifth opening OP5 defined in the first color filter layer 581 may overlap (or overlap at least a portion) the third color filter layer 585 in a plan view.

According to an embodiment, a sixth opening OP6 and a seventh opening OP7 may be defined in the second color filter layer 583. The sixth opening OP6 defined in the second color filter layer 583 may overlap (or overlap at least a portion) the first color filter layer 581 in a plan view. The seventh opening OP7 defined in the second color filter layer 583 may overlap (or overlap at least a portion) the third color filter layer 585 in a plan view.

According to an embodiment, an eighth opening OP8 and a ninth opening OP9 may be defined in the third color filter layer 585. The eighth opening OP8 defined in the third color filter layer 585 may overlap (or overlap at least a portion) the first color filter layer 581 in a plan view. The ninth opening OP9 defined in the third color filter layer 585 may overlap (or overlap at least a portion) the second color filter layer 583 in a plan view.

According to an embodiment, at least a portion of the first color filter layer 581 may be exposed through the sixth opening OP6 defined in the second color filter layer 583 and the eighth opening OP8 defined in the third color filter layer 585. The first color filter layer 581 may contact (e.g., directly contact) the first quantum dot layer 561 through the sixth opening OP6, and may contact (e.g., directly contact) the lower surface 600-2 of the upper substrate 600 through the eighth opening OP8. For example, the first color filter layer 581 may contact (e.g., directly contact) the first quantum dot layer 561 in the direction (e.g., −z direction) of the lower surface 600-2 of the upper substrate 600. The first color filter layer 581 may contact (e.g., directly contact) the lower surface 600-2 of the upper substrate 600 in a direction (e.g., +z direction) of the upper surface 600-1 of the upper substrate 600.

Accordingly, in the first pixel PX1, the light of the first wavelength band may be emitted to the outside through the upper substrate 600. For example, the light of the third wavelength band emitted by the first light-emitting device OLED1 may pass through the first quantum dot layer 561 to be converted into the light of the first wavelength band, and the converted light may pass through the first color filter layer 581 to be filtered. Thus, the light of the first wavelength band may be emitted to the outside through the upper substrate 600 in the first pixel PX1. The light emitted by the first light-emitting device OLED1 may pass through the first quantum dot layer 561 and the first color filter layer 581, and color purity of the light emitted through the upper substrate 600 in the first pixel PX1 may be improved.

According to an embodiment, at least a portion of the second color filter layer 583 may be exposed through the fourth opening OP4 defined in the first color filter layer 581 and the ninth opening OP9 defined in the third color filter layer 585. The second color filter layer 583 may contact (e.g., directly contact) the lower surface 600-2 of the upper substrate 600 through the fourth opening OP4 and the ninth opening OP9. For example, the second color filter layer 583 may contact (e.g., directly contact) the second quantum dot layer 563 in the direction (e.g., −z direction) of the lower surface 600-2 of the upper substrate 600. The second color filter layer 583 may contact (e.g., directly contact) the lower surface 600-2 of the upper substrate 600 in the direction (e.g., +z direction) of the upper surface 600-1 of the upper substrate 600.

Accordingly, in the second pixel PX2, the light of the second wavelength band may be emitted to the outside through the upper substrate 600. For example, the light of the third wavelength band emitted by the second light-emitting device OLED2 may pass through the second quantum dot layer 563 to be converted into the light of the second wavelength band, and the converted light may pass through the second color filter layer 583 to be filtered. Thus, the light of the second wavelength band may be emitted to the outside through the upper substrate 600 in the second pixel PX2. The light emitted by the second light-emitting device OLED2 may pass through the second quantum dot layer 563 and the second color filter layer 583. Thus, color purity of the light emitted through the upper substrate 600 in the second pixel PX2 may be improved.

According to an embodiment, at least a portion of the third color filter layer 585 may be exposed through the fifth opening OP5 defined in the first color filter layer 581 and the seventh opening OP7 defined in the second color filter layer 583. The third color filter layer 585 may contact (e.g., directly contact) the light-transmissive layer 565 through the fifth opening OP5 and the seventh opening OP7. For example, the third color filter layer 585 may contact (e.g., directly contact) the light-transmissive layer 565 in the direction (e.g., −z direction) of the lower surface 600-2 of the upper substrate 600, and the third color filter layer 585 may contact (e.g., directly contact) the lower surface 600-2 of the upper substrate 600 in the direction (e.g., +z direction) of the upper surface 600-1 of the upper substrate 600.

Accordingly, in the third pixel PX3, the light of the third wavelength band may be emitted to the outside through the upper substrate 600. For example, the light of the third wavelength band emitted by the third light-emitting device OLED3 may pass through the light-transmissive layer 565 to be filtered, and pass through the third color filter layer 585. Thus, the light of the third wavelength band may be emitted to the outside through the upper substrate 600 in the third pixel PX3. The light emitted by the third light-emitting device OLED3 may pass through the light-transmissive layer 565 and the third color filter layer 585, and color purity of the light emitted through the upper substrate 600 in the third pixel PX3 may be improved.

According to an embodiment, at least two color filter layers may be overlappingly present between the first pixel PX1, the second pixel PX2, and the third pixel PX3. For example, at least two of the first color filter layer 581, the second color filter layer 583, and the third color filter layer 585 may overlap in each of the first pixel PX1, the second pixel PX2, and the third pixel PX3. FIG. 6 illustrates that the first color filter layer 581, the second color filter layer 583, and the third color filter layer 585 are present between the first pixel PX1, the second pixel PX2, and the third pixel PX3 in a cross-sectional view. For example, three color filter layers 581, 583, and 585 (i.e., three first to third color filter layers 581, 583, and 585) may overlap an area between adjacent ones of the first pixel PX1, the second pixel PX2, and the third pixel PX3. The overlapping color filter layers 581, 583, and 585 may serve as a black matrix. This is because, in case that the first color filter layer 581 transmits only light having a wavelength in the first wavelength band, the second color filter layer 583 transmits only light having a wavelength in the second wavelength band, and the third color filter layer 585 transmits only light having a wavelength in the third wavelength band, light of any wavelength is theoretically unable to pass through these overlapped color filter layers.

According to an embodiment, the first color filter layer 581, the second color filter layer 583, and the third color filter layer 585 may be overlappingly arranged between the upper substrate 600 and the bank 500. The overlapping arrangement of the first color filter layer 581, the second color filter layer 583, and the third color filter layer 585 between the upper substrate 600 and the bank 500 may enable (or form) a step difference between the upper substrate 600 and the bank 500. The step difference may be maintained constant.

According to an embodiment, a protective layer 460 and the filler 400 may be disposed between the lower substrate 100 and the upper substrate 600. The filler 400 may be between the thin-film encapsulation layer 300 and the protective layer 460, and the protective layer 460 may be between the filler 400 and the bank 500.

According to an embodiment, the filler 400 may function as a buffer against external pressure, or the like. The filler 400 may include at least one organic material of methyl silicone, phenyl silicone, and polyimide. However, embodiments are not limited thereto, and the filler 400 may include at least one organic sealant of a urethane-based resin, an epoxy-based resin, and an acrylic resin. For example, the filler 400 may include an inorganic sealant such as silicon.

According to an embodiment, the protective layer 460 may be arranged on the entirety of the filler 400. The protective layer 460 may cover the first quantum dot layer 561, the second quantum dot layer 563, and the light-transmissive layer 565. For example, because a process of coupling (or connecting) the lower substrate 100 with the upper substrate 600 is performed after color filter layers and quantum dot layers are formed on the lower surface 600-2 of the upper substrate 600, the protective layer 460 may cover the first quantum dot layer 561, the second quantum dot layer 563, and the light-transmissive layer 565 formed on the lower surface 600-2 of the upper substrate 600. The protective layer 460 may protect the first quantum dot layer 561, the second quantum dot layer 563, and the light-transmissive layer 565.

According to an embodiment, the protective layer 460 may be a single layer including an organic material or an inorganic material or a multi-layer formed by stacking single layers each including an organic material or an inorganic material. The protective layer 460 may include a commercial polymer such as benzocyclobutene (BCB), polyimide (PI), hexamethyldisiloxane (HMDSO), polymethyl methacrylate (poly(methyl 2-methylpropenoate), PMMA), or polystyrene (PS), a polymer derivative having a phenol-based group, an acryl-based polymer, an imide-based polymer, an acryl ether-based polymer, an amide-based polymer, a fluorine-based polymer, a p-xylene-based polymer, a vinyl alcohol-based polymer, a blend thereof, or the like. According to an embodiment, the protective layer 460 may include SiOₓ, SiNₓ, SiOₓN_{y}, Al₂O₃, TiO₂, Ta₂O₅, HfO₂, ZnO or the like. The ZnO may be a zinc oxide (ZnO) and/or a zinc peroxide (ZnO₂).

According to an embodiment, a column spacer 450 may be between the lower substrate 100 and the upper substrate 600. The column spacer 450 may be between the thin-film encapsulation layer 300 and the protective layer 460. The column spacer 450 may overlap or be overlapped by (or at least partially overlapped) the bank 500. The column spacer 450 may overlap (or at least partially overlap) the pixel defining layer 120 arranged thereunder in a plan view. For example, the column spacer 450 may not overlap the first, second, and third emission areas EA1, EA2, and EA3 of the first, second, and third light-emitting devices OLED1, OLED2, and OLED3 in a plan view.

According to an embodiment, the column spacer 450 and the bank 500 may include a same material. However, embodiments are not limited thereto. For example, the column spacer 450 may include a material different from that included in the bank 500.

Referring to FIGS. 5 and 6, the bank 500 may be arranged in the non-display area NDA (e.g., refer to FIG. 1) of the display apparatus 1. The bank 500 may be arranged in the entirety of the non-display area NDA or in a portion of the non-display area NDA. According to another embodiment, although not shown in the drawings, the bank 500 arranged in the non-display area NDA may include a dummy opening. The dummy opening may have the same pattern as the first opening OP1, the second opening OP2, and the third opening OP3. However, for convenience of description, description of a display apparatus without dummy openings in the bank 500 arranged in the non-display area NDA is provided below.

According to an embodiment, the insulating layer 30, the thin-film encapsulation layer 300, the filler 400, and the protective layer 460 may be sequentially arranged on the lower substrate 100. Since the non-display area NDA (e.g., refer to FIG. 1) provides no image, no light-emitting devices may be arranged in the non-display area NDA. However, drivers or the like may be arranged on the insulating layer 30 of the non-display area NDA.

According to an embodiment, the bank 500 may be arranged on the protective layer 460. In case that a dummy opening is arranged in the non-display area NDA (e.g., refer to FIG. 1), a dummy quantum dot layer and a dummy light-transmissive layer may be arranged on the dummy opening. For example, a first dummy quantum dot layer and the first quantum dot layer 561 may be (or be disposed on) a same layer. A second dummy quantum dot layer and the second quantum dot layer 563 may be (or be disposed on) a same layer. A dummy light-transmissive layer and the light-transmissive layer 565 may be (or be disposed on) a same layer. The first dummy quantum dot layer, the second dummy quantum dot layer, and the dummy light-transmissive layer may be arranged in the dummy opening. Although not shown in the drawings, the second color filter layer 583, the first color filter layer 581, and the third color filter layer 585 may be sequentially arranged on the first dummy quantum dot layer, the second dummy quantum dot layer, and the dummy light-transmissive layer arranged in the dummy opening. The second color filter layer 583, the first color filter layer 581, and the third color filter layer 585 may cover all of the first dummy quantum dot layer, the second dummy quantum dot layer, and the dummy light-transmissive layer.

The second color filter layer 583, the first color filter layer 581, and the third color filter layer 585 sequentially arranged in the dummy opening (or the non-display area NDA) may serve as a black matrix. For example, since the second color filter layer 583, the first color filter layer 581, and the third color filter layer 585 sequentially stacked one another do not transmit the light of the first to third wavelength bands, the light of the first to third wavelength bands may not be emitted toward the upper substrate 600 overlapping the first dummy quantum dot layer, the second dummy quantum dot layer, and the dummy light-transmissive layer in a plan view.

Referring to FIG. 5, the first, second, and third openings OP1, OP2, and OP3 may be defined in the bank 500 of the display area DA. Multiple first openings OP1, multiple second openings OP2, and multiple third openings OP3 may be included in the bank 500 of the display area DA. According to an embodiment, a first dummy opening DOP1 may be defined in the bank 500 of the display area DA. Multiple first dummy openings DOP1 may be included in the bank 500 of the display area DA. According to another embodiment, although not shown in the drawings, the first dummy opening DOP1 may not be arranged in the bank 500 of the display area DA. The first quantum dot layer 561, the second quantum dot layer 563, and the light-transmissive layer 565 may be arranged adjacent to one another. However, for convenience of description, description of the first dummy opening DOP1 arranged in the bank 500 of the non-display area NDA (e.g., refer to FIG. 1) is not provided below.

As described above, the first quantum dot layer 561 may be arranged within the first opening OP1. The second quantum dot layer 563 may be arranged within the second opening OP2. The light-transmissive layer 565 may be arranged within the third opening OP3.

According to an embodiment, the first quantum dot layer 561 and the light-transmissive layer 565 adjacent (e.g., closest) to the first quantum dot layer 561 may be located on a same row. For example, the first quantum dot layer 561 and the light-transmissive layer 565 adjacent (e.g., closest) to the first quantum dot layer 561 may be located apart from each other in a first direction (e.g., x direction), and the first quantum dot layer 561 and the light-transmissive layer 565 may be alternately arranged on a same row.

According to an embodiment, the first quantum dot layer 561 and the second quantum dot layer 563 adjacent (e.g., closest) to the first quantum dot layer 561 may be located on different rows. For example, the first quantum dot layer 561 and the second quantum dot layer 563 adjacent (e.g., closest) to the first quantum dot layer 561 may be diagonally spaced apart from each other. Second quantum dot layers 563 may be arranged (or spaced) apart from each other in the first direction (e.g., x direction) with the first dummy opening DOP1 therebetween.

For example, the second quantum dot layer 563 and the first dummy opening DOP1 may be alternately arranged on a first row 1N. The first quantum dot layer 561 and the light-transmissive layer 565 may be alternately arranged on a second row 2N. The second quantum dot layer 563 and the first dummy opening DOP1 may be alternately arranged on a third row 3N. This arrangement may be repeated until an N-th row.

According to an embodiment, the bank 500 arranged in the display area DA may include the first dummy opening DOP1. Because the first dummy opening DOP1 is defined in the bank 500 arranged in the display area DA, a display quality of the display apparatus 1 may be improved.

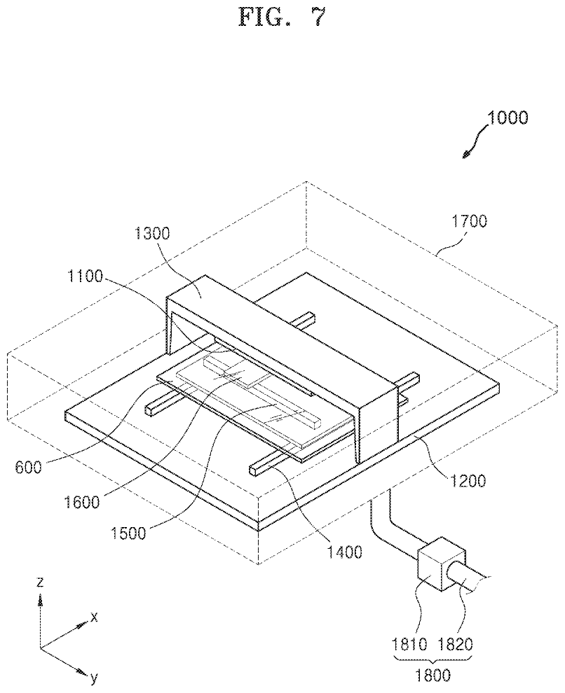

FIG. 7 is a schematic perspective view of an apparatus 1000 for manufacturing a display apparatus, according to an embodiment.

Referring to FIG. 7, the apparatus 1000 may include a discharge part 1100, a body part 1200, a support 1300, a first driver 1400, a second driver 1500, and a stage 1600.

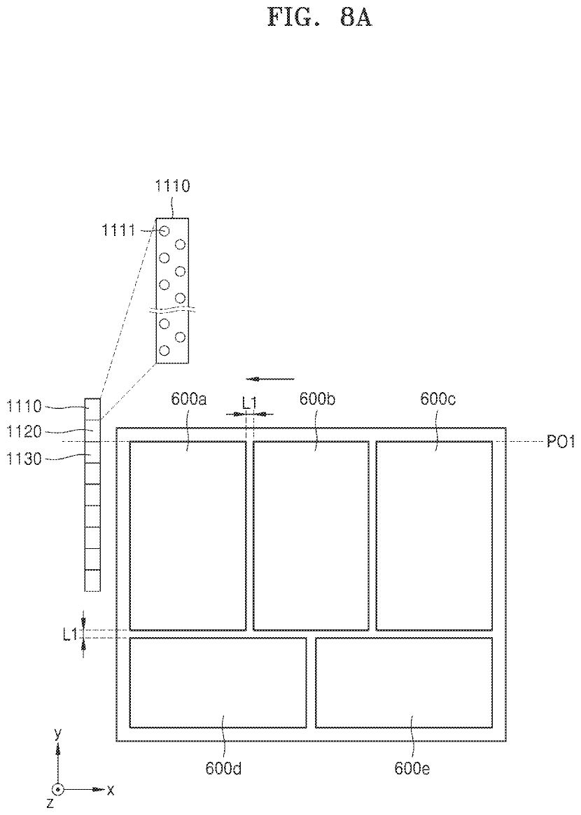

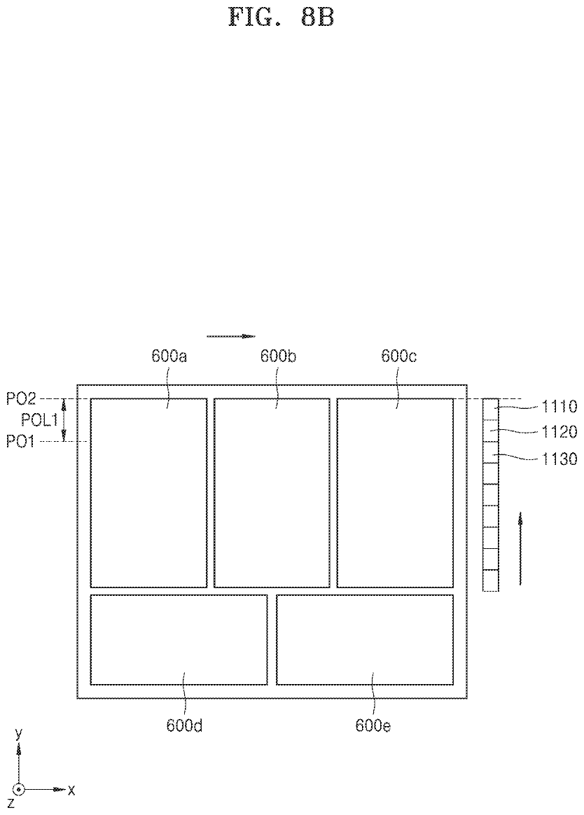

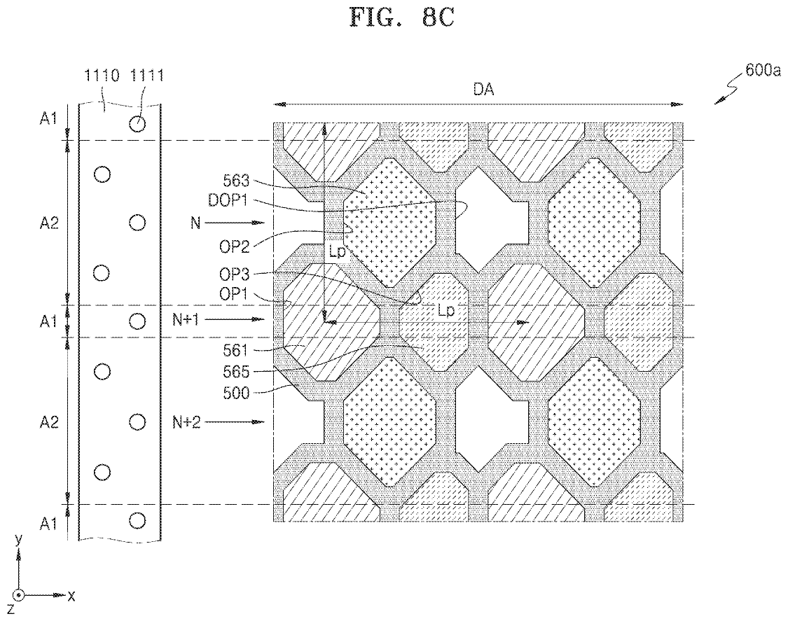

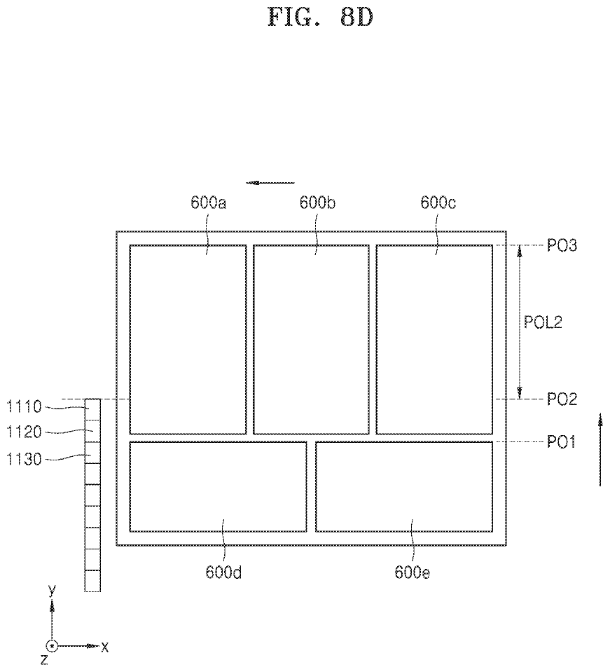

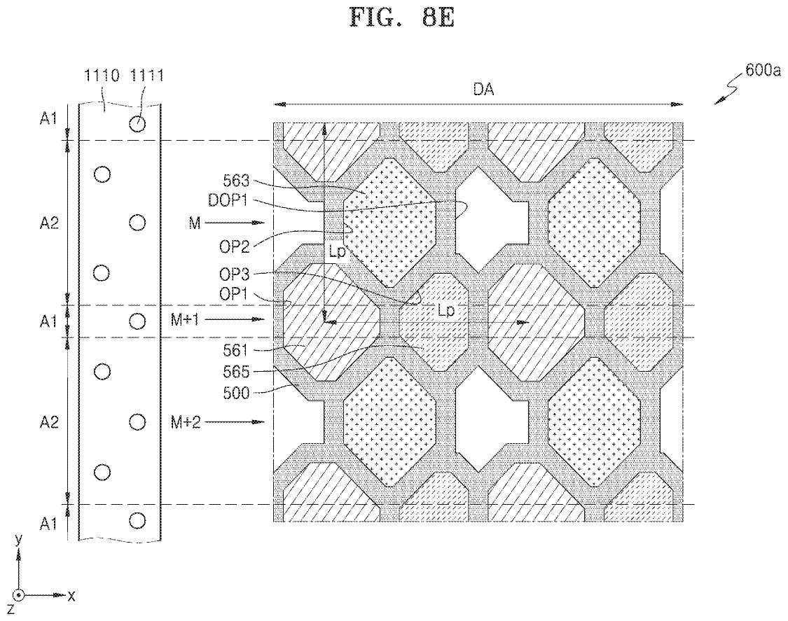

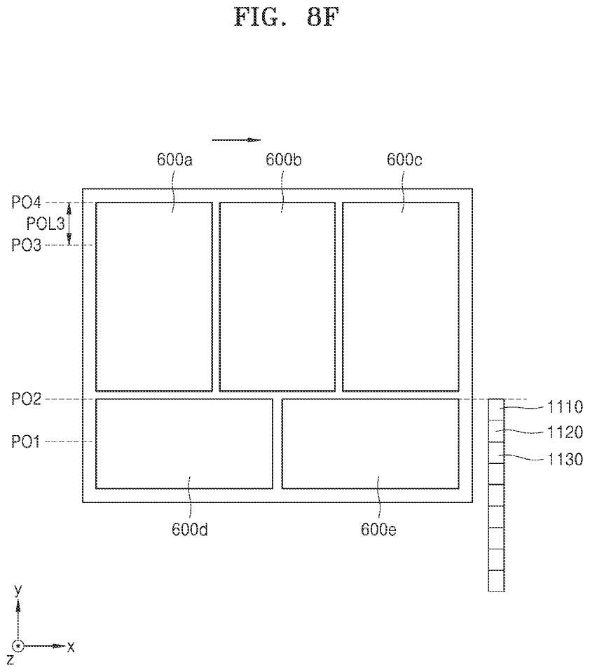

The discharge part 1100 may include head parts 1110, 1120, and 1130 (e.g., refer to FIG. 8A). Each of the head parts 1110, 1120, and 1130 (e.g., refer to FIG. 8A) may include at least one nozzle. Each of the head parts 1110, 1120, and 1130 (e.g., refer to FIG. 8A) may include multiple nozzles. The nozzles may be arranged in a row or in a zigzag manner. For convenience of description, description of the multiple nozzles arranged in a zigzag manner are provided below.

The head parts 1110, 1120, and 1130 may be lined up (or arranged) in a second direction (e.g., y direction of FIG. 7). The nozzles arranged in each of the head parts 1110, 1120, and 1130 may be arranged (or spaced) apart from one another in the second direction (e.g., y direction).

In case that the body part 1200 is formed in various shapes, the body part 1200 may be arranged on a surface of other machine tools, a floor of a building, or the like. For example, the body part 1200 may be formed in a plate shape. According to another embodiment, the body part 1200 may be formed in a table shape by connecting (e.g., physically connecting or extending) multiple frames to one another. According to another embodiment, the body part 1200 may be formed in a box shape by arranging multiple frames and multiple plates. However, the shape of the body part 1200 is not limited thereto, and the body part 1200 may include any structure (or shape) capable of supporting a structure (or element or the like) arranged thereon.

The support 1300 may be connected (e.g., physically connected or extended) to the body part 1200 and may support the discharge part 1100. According to an embodiment, the support 1300 may be fixed to the body part 1200. According to another embodiment, the support 1300 may be arranged on the body part 1200, and may be linearly movable. A driver (e.g., gantry) may be arranged between the support 1300 and the body part 1200, and the support 1300 may linearly move (or be transported) on the driver (e.g., gantry). However, for convenience of description, description of the support 1300 fixed to the body part 1200 is provided below.

The discharge part 1100 may be fixed onto the support 1300. According to another embodiment, the discharge part 1100 may be arranged to be linearly movable on the support 1300. A cylinder, a linear motor, a pair of a motor and a ball screw, a pair of a motor and a rack gear, or the like may be arranged on at least one of the discharge part 1100 and the support 1300, and the discharge part 1100 may linearly move (or be transported) in the first direction (e.g., x direction of FIG. 7). However, for convenience of description, description of the discharge part 1100 fixed to the support 1300 is provided below.

The first driver 1400 may be arranged between the body part 1200 and the stage 1600. The first driver 1400 may linearly move (or transport) the stage 1600 in the first direction (e.g., x direction). The first driver 1400 may be provided in various shapes. According to an embodiment, the first driver 1400 may be fixed to the body part 1200, and may include a cylinder having a shaft connected (e.g., physically connected or extended) to the second driver 1500. According to another embodiment, the first driver 1400 may include a motor and a ball screw. The motor may be fixed to the body part 1200, and the ball screw may be connected (e.g., physically connected or extended) to the motor and the second driver 1500. According to another embodiment, the first driver 1400 may include a linear motor connected (e.g., physically connected or extended) to the second driver 1500. The first driver 1400 is not limited thereto, and may include any structure and device connected (e.g., physically connected or extended) to the second driver 1500 to linearly move (or transport) the stage 1600 in the first direction (e.g., x direction).

The second driver 1500 may be arranged on the first driver 1400. The second driver 1500 may linearly move (or transport) the stage 1600 in the second direction (e.g., y direction of FIG. 7). The second driver 1500 may have a similar shape to the first driver 1400. For convenience of description, description of the first driver 1400 and the second driver 1500 including linear motors is provided below.

The stage 1600 may be connected (e.g., physically connected or extended) to the second driver 1500, and may be linearly movable in at least one direction of the first direction (e.g., x direction) and the second direction (e.g., y direction) according to operations of the first driver 1400 and the second driver 1500. The upper substrate 600 may be seated (or disposed) on the stage 1600. In case that the stage 1600 linearly moves (or is transported) in at least one direction of the first direction and the second direction, the upper substrate 600 may also linearly move (or be transported) in the at least one direction of the first direction and the second direction.

The chamber 1700 may form an internal space therein, and the discharge part 1100, the body part 1200, the support 1300, the first driver 1400, the second driver 1500, and the stage 1600 may be arranged within the chamber 1700 (or the internal space of the chamber 1700). A portion of the chamber 1700 may be opened, and a gate valve or the like may be arranged on the open portion of the chamber 1700 to open or close the open portion of the chamber 1700.

A pressure adjuster 1800 may be connected (e.g., physically connected or extended) to the chamber 1700. The pressure adjuster 1800 may include a pipe 1810, and a pump 1820 provided on the pipe 1810. The pump 1820 may discharge an internal gas of the chamber 1700 to the outside or may introduce an outside gas into the chamber 1700.

The apparatus 1000 may provide droplets to the upper substrate 600, and form a quantum dot layer and a light-transmissive layer on the upper substrate 600.

FIGS. 8A to 8F are schematic plan views illustrating a method of manufacturing a display apparatus, according to an embodiment.

Referring to FIG. 8A, a first quantum dot layer 561 (e.g., refer to FIG. 8C), a second quantum dot layer 563 (e.g., refer to FIG. 8C), and a light-transmissive layer 565 (e.g., refer to FIG. 8C) of a display apparatus according to an embodiment may be formed via inkjet printing.

According to an embodiment, an upper substrate 600 (e.g., refer to FIG. 7) may reciprocate in a first direction (e.g., x direction). Multiple head parts 1110, 1120, and 1130 may be repeatedly arranged in a second direction (e.g., y direction) perpendicular to the first direction, which is a movement direction (or transport direction) of the upper substrate 600. The head parts 1110, 1120, and 1130 may include a first head part 1110 discharging first ink, a second head part 1120 discharging second ink, and a third head part 1130 discharging third ink. The first ink may include first quantum dots 1152 (e.g., refer to FIG. 3), first scatterers 1153 (e.g., refer to FIG. 3), and a first photosensitive polymer 1151 (e.g., refer to FIG. 3) forming the first quantum dot layer 561 (e.g., refer to FIG. 8C). The second ink may include second quantum dots 1162 (e.g., refer to FIG. 3), second scatterers 1163 (e.g., refer to FIG. 3), and a second photosensitive polymer 1161 (e.g., refer to FIG. 3) forming the second quantum dot layer 563 (e.g., refer to FIG. 8C). The third ink may include third scatterers 1173 (e.g., refer to FIG. 3) and a third photosensitive polymer 1171 (e.g., refer to FIG. 3) forming the light-transmissive layer 565 (e.g., refer to FIG. 8C).

According to an embodiment, each of the head parts 1110, 1120, and 1130 may include at least two nozzles 1111. The nozzles 1111 may receive the ink (e.g., first, second, and third inks) from the head parts 1110, 1120, and 1130 and discharge the ink (e.g., first, second, and third inks) toward the upper substrate 600. The upper substrate 600 may include one or more coating regions (e.g. at least one of a plurality of coating regions 600a, 600b, 600c, 600d, and 600e) on which the ink (e.g., first, second, and third inks) is discharged and coated. For example, the upper substrate 600 may include single coating region 600a, 600b, 600c, 600d, or 600e. According to another embodiment, the upper substrate 600 may include multiple coating regions 600a, 600b, 600c, 600d, and 600e. For convenience of description, description of the upper substrate 600 including the multiple coating regions 600a, 600b, 600c, 600d, and 600e is provided below.

In case that the coating regions 600a, 600b, 600c, 600d, and 600e are coated (e.g., completely coated) with the ink (e.g., first to third inks), the coating regions 600a, 600b, 600c, 600d, and 600e may be separated from one another to form a color panel 20. The upper substrate 600 may be split (or separated) from one other by cutting boundaries between adjacent ones of the coating regions 600a, 600b, 600c, 600d, and 600e. The coating regions 600a, 600b, 600c, 600d, and 600e may refer to a shape formed by connecting respective edges of outermost openings OP1, OP2, and OP3 (e.g., refer to FIG. 8C) of the openings OP1, OP2, and OP3 (i.e., the first to third openings OP1, OP2, and OP3) of the bank 500 (e.g., refer to FIG. 8C) corresponding to the pixels (or emission area) of the light-emitting panel 10 (e.g., refer to FIG. 2). For example, each of the coating regions 600a, 600b, 600c, 600d, and 600e may be a contour defined by the edges of the outmost ones of the openings OP1, OP2, and OP3. According to another embodiment, the coating regions 600a, 600b, 600c, 600d, and 600e may refer to regions where respective centers of the outermost openings OP1, OP2, and OP3 of the openings OP1, OP2, and OP3 of the bank 500 corresponding to the pixels of the light-emitting panel 10 are connected to one another. For example, each of the coating regions 600a, 600b, 600c, 600d, and 600e may be a contour defined by the centers of the outmost ones of the openings OP1, OP2, and OP3. According to another embodiment, the coating regions 600a, 600b, 600c, 600d, and 600e may also refer to regions where respective centers of inks accommodated in the outermost openings OP1, OP2, and OP3 are connected to one another. According to another embodiment, the coating regions 600a, 600b, 600c, 600d, and 600e may be regions including the outermost openings OP1, OP2, and OP3 and a dummy opening.

The coating regions 600a, 600b, 600c, 600d, and 600e may be coating targets (or targets to be coated), and surfaces heading toward the nozzles 1111 of the surfaces of the coating regions 600a, 600b, 600c, 600d, and 600e may be coating target surfaces (or target surfaces to be coated). The ink, which is a coating material, may be liquid.

According to an embodiment, the upper substrate 600 (e.g., refer to FIG. 7) may be seated (or disposed) on a stage 1600 (e.g., refer to FIG. 7), and the stage 1600 may reciprocate in the first direction (e.g., x direction). The stage 1600 may move (or be transported) by a distance in the second direction (e.g., y direction) different from the first direction. The head parts 1110, 1120, and 1130 may scan the coating regions 600a, 600b, 600c, 600d, and 600e, and discharge the ink (e.g., first to third inks) at locations. The scanning of the head parts 1110, 1120, and 1130 may be performed at least once. In case that the scanning is performed multiple times, the times of the scanning may include first scanning and second scanning. The first scanning may be downward scanning, and the second scanning may be upward scanning. According to another embodiment, the times of the scanning may be performed in a same direction. For example, the times of the scanning may be performed upwards. In other embodiments, the times of the scanning may be performed downwards. However, for convenience of description, description of a method of manufacturing a display apparatus performed by scanning multiple times including the first scanning and the second scanning is provided below.

According to an embodiment, in case that the coating regions 600a, 600b, 600c, 600d, and 600e reciprocate in the first direction (e.g., x direction), the first head part 1110 may discharge the first ink to the first opening OP1 (e.g., refer to FIG. 8C). The first ink may be discharged to the first opening OP1, and thus the first quantum dot layer 561 may be formed.

The coating regions 600a, 600b, 600c, 600d, and 600e may be spaced apart from one another by a same distance L1 in the first direction (e.g., x direction) and the second direction (e.g., y direction). The distance L1 may be a multiple of a natural number that is one or more times a distance between the centers of openings arranged on the same coating region 600a, 600b, 600c, 600d, or 600e and accommodating the same ink. For example, the distance L1 may be a multiple of a natural number that is one or more times a distance Lp between respective centers of first quantum dot layers 561 of FIG. 8C.

According to an embodiment, since nozzles 1111 positioned in a first area A1 (e.g., refer to FIG. 8C) of the first head part 1110 pass over the first openings OP1 (e.g., refer to FIG. 8C), the first ink may be discharged through the nozzles 1111 positioned in the first area A1. However, since nozzles 1111 positioned in a second area A2 (e.g., refer to FIG. 8C) of the first head part 1110 does not pass over the first openings OP1, the first ink may not be discharged through the nozzles 1111 positioned in the second area A2. In this case, a material such as a first scatterer (e.g., TiO₂) corresponding to a high density from among the components included in the first ink may precipitate in the nozzles 1111 not spraying ink for a long time. In case that a precipitated first scatterer (e.g., TiO₂) is discharged, a concentration of the first scatterer (e.g., TiO₂) within the first quantum dot layer 561 may increase, and thus a stain may be generated in the first quantum dot layer 561.

Although the description only describes the stain generated in the first quantum dot layer 561 (e.g., refer to FIG. 8C), stains may also be generated in the second quantum dot layer 563 (e.g., refer to FIG. 8C) and the light-transmissive layer 565 (e.g., refer to FIG. 8C) for the same reason as mentioned above. For example, multiple stains may be generated in the light-transmissive layer 565 having a higher scatterer concentration than those of the first quantum dot layer 561 and the second quantum dot layer 563.

To address this problem, the same nozzles 1111 may be continuously used. For example, the first quantum dot layers 561 may be arranged in the first openings OP1 (e.g., refer to FIG. 8C) of the bank 500 (e.g., refer to FIG. 8C) arranged in the first direction (e.g., x direction) in case that the upper substrate 600 (e.g., refer to FIG. 6) moves (or is transported) in the first direction. In case that the upper substrate 600 moves (or is transported) in the second direction (e.g., y direction) and the upper substrate 600 moves (or is transported) back in the first direction or in an opposite direction to the first direction, the nozzles 1111 arranged in the first area A1 may discharge the first ink, and the nozzles 1111 arranged in the second area A2 may not discharge the first ink. Such a process may be performed on the entire surfaces of the coating regions 600a, 600b, 600c, 600d, and 600e. For example, only the nozzles 1111 in the first area A1 first used for the entire surfaces of the coating regions 600a, 600b, 600c, 600d, and 600e may be continuously (or repeatedly) used. Thus, due to the use of only the nozzles 1111 arranged in the first area A1 without using the nozzles 1111 of the second area A2 of which the concentration of the first scatterer has been increased, the concentrations of the first scatterers respectively included in the first quantum dot layers 561 (e.g., refer to FIG. 8C) may be uniform all over the coating regions 600a, 600b, 600c, 600d, and 600e.

For example, referring to FIG. 8A, the coating regions 600a, 600b, 600c, 600d, and 600e may be arranged at a first position PO1, which is an initial position. Thereafter, according to a movement of the stage 1600, the coating regions 600a, 600b, 600c, 600d, and 600e may move in a left direction, which is an opposite direction to the first direction, based on FIG. 8A. The nozzles 1111 arranged in the first area A1 (e.g., refer to FIG. 8C) in the first head part 1110 may supply the first ink to the first opening OP1. In this case, nozzles 1111 arranged in the first area A1 and in a portion where the upper substrate 600 is not arranged may not operate. For example, a portion of the nozzles 1111 arranged in the first area A1, which is disposed in a region out of the upper substrate 600 (e.g., refer to FIG. 7), may not operate. For example, in case that the coating regions 600a, 600b, 600c, 600d, and 600e move (or are transported) based on the movement described in FIG. 8A, nozzles arranged in two head parts (e.g., first head part 1110 and second head part 1120) on the upper side not overlapping the upper substrate 600 may not operate.

Since the coating regions 600a, 600b, 600c, 600d, and 600e reciprocate in the horizontal direction of FIG. 8A or move (or are transported) in the left direction of FIG. 8A, ink may be supplied to a moving path of the coating regions 600a, 600b, 600c, 600d, and 600e along movement thereof and supplied (e.g., only supplied) on overlapping areas between the head parts 1110, 1120, and 1130 and the coating regions 600a, 600b, 600c, 600d, and 600e in a plan view.

In case that the coating regions 600a, 600b, 600c, 600d, and 600e move (or are transported) in the opposite direction to the first direction (e.g., x direction), the second head part 1120 may supply the second ink and the third head part 1130 may supply the third ink.

Referring to FIG. 8B, after the above-described process is completed, the coating regions 600a, 600b, 600c, 600d, and 600e may move (or be transported) in the second direction (e.g., y direction). The second direction may be a direction perpendicular to the first direction (e.g., x direction) as described above, and may be a direction going from the lower side to the upper side with reference to FIG. 8B.

In case that the coating regions 600a, 600b, 600c, 600d, and 600e are arranged as described above, the coating regions 600a, 600b, 600c, 600d, and 600e may be arranged on the left side of the head parts 1110, 1120, and 1130, and may be arranged at a second position PO2 different from the first position PO1.

In case that the coating regions 600a, 600b, 600c, 600d, and 600e are arranged at the second position PO2 as described above, the coating regions 600a, 600b, 600c, 600d, and 600e may move (or be transported) from the first position PO1 to the second position PO2 by a first position distance POL1. The first position distance POL1 may be a multiple of a natural number of 1 or more of a distance Lp between quantum dot layers (or distance between light-transmissive layers) corresponding to two adjacent pixels. For example, the first position distance POL1 may be a multiple of a natural number of 1 or more of a distance Lp between two first quantum dot layers 561 (e.g., refer to FIG. 8C) having a same material and arranged adjacent to each other. For example, the distance Lp between the two first quantum dot layers 561 adjacent to each other may be about 10 μm. The first position distance POL1 may be N times (where N is a natural number equal to or greater than 1) of about 10 μm (e.g., about 20 μm or about 30 μm). According to another embodiment, the first position distance POL1 may be a multiple of a natural number of 1 or more of a distance between two second quantum dot layers 563 having a same material and arranged adjacent to each other. According to another embodiment, the first position distance POL1 may be a multiple of a natural number of 1 or more of a distance between two light-transmissive layers 565 arranged adjacent to each other. The first position distance POL1 may vary according to formation of each quantum dot layer or a light-transmissive layer. However, for convenience of description, description of first quantum dot layers 561 arranged adjacent to each other by the first position distance POL1 is provided below.

After the coating regions 600a, 600b, 600c, 600d, and 600e are arranged to correspond to the second position PO2 as described above, the coating regions 600a, 600b, 600c, 600d, and 600e may move in a right direction of FIG. 8B, and the first ink may be supplied to the coating regions 600a, 600b, 600c, 600d, and 600e. As shown in FIG. 8C, similar to the case where the coating regions 600a, 600b, 600c, 600d, and 600e move and the first ink is supplied to the coating regions 600a, 600b, 600c, 600d, and 600e, only the nozzles 1111 arranged in the first area A1 of the first head part 1110 may supply the first ink to the first opening OP1. The nozzles 1111 arranged in the second area A2 may not supply the first ink.

In case that the above-described process is completed, the coating regions 600a, 600b, 600c, 600d, and 600e may move (or be transported) in the second direction (e.g., y direction) as shown in FIG. 8D. The coating regions 600a, 600b, 600c, 600d, and 600e may be arranged at a third position PO3. Similar to the first position distance POL1, a second position distance POL2 that is a difference between the second position PO2 and the third position PO3 may be a multiple of a natural number of 1 or more of the distance Lp between two first quantum dot layers 561 (e.g., refer to FIG. 8C) adjacent to each other. According to another embodiment, similar to the first position distance POL1, the second position distance POL2 may be a multiple of a natural number of 1 or more of a distance between two second quantum dot layers 563 (e.g., refer to FIG. 8C) adjacent to each other or a distance between two light-transmissive layers 565 (e.g., refer to FIG. 8C) adjacent to each other.

In case that, as described above, the first head part 1110 supplies the first ink to the coating regions 600a, 600b, 600c, 600d, and 600e while the coating regions 600a, 600b, 600c, 600d, and 600e arranged at the third position PO3 are moving, the same nozzles 1111 as the nozzles 1111 in the first head part 1110 having supplied the first ink to the coating regions 600a, 600b, 600c, 600d, and 600e arranged at the second position PO2 may supply the first ink.

For example, nozzles 1111 having supplied the first ink to first openings OP1 arranged on an N-th column (where N is a natural number equal to or greater than 1) of FIG. 8C may supply the first ink to first openings OP1 arranged on an M-th column (where M is a natural number equal to or greater than 1 and different from N) of FIG. 8E. Nozzles 1111 having supplied the first ink to first openings OP1 arranged on an (N+1)th column of FIG. 8C may supply the first ink to first openings OP1 arranged on an (M+1)th column of FIG. 8E. Nozzles 1111 having supplied the first ink to first openings OP1 arranged on an (N+2)th column of FIG. 8C may supply the first ink to first openings OP1 arranged on an (M+2)th column of FIG. 8E. The nozzles 1111 arranged in the first area A1 may supply the first ink, and the nozzles 1111 arranged in the second area A2 may not supply the first ink.

In case that this process is completed, the coating regions 600a, 600b, 600c, 600d, and 600e may be arranged at a fourth position PO4, as shown in FIG. 8F. Similar to the first position distance POL1 and the second position distance POL2, a third position distance POL3 that is a difference between the fourth position PO4 and the third position PO3 may be a multiple of a natural number of 1 or more of the distance Lp (e.g., refer to FIG. 8E) between two first quantum dot layers 561 (e.g., refer to FIG. 8E) adjacent to each other. According to another embodiment, similar to the first position distance POL1 and the second position distance POL2, the third position distance POL3 may be a multiple of a natural number of 1 or more of a distance between two second quantum dot layers 563 (e.g., refer to FIG. 8E) adjacent to each other or a distance between two light-transmissive layers 565 (e.g., refer to FIG. 8E) adjacent to each other.

In case that the coating regions 600a, 600b, 600c, 600d, and 600e are arranged at the fourth position PO4 as described above, the coating regions 600a, 600b, 600c, 600d, and 600e may be arranged on the right side of the head parts 1110, 1120, and 1130. The coating regions 600a, 600b, 600c, 600d, and 600e may move (or be transported) from the right side of the head parts 1110, 1120, and 1130 to the left side thereof, and the first head part 1110 may supply the first ink to the coating regions 600a, 600b, 600c, 600d, and 600e during movement (or transportation) of the coating regions 600a, 600b, 600c, 600d, and 600e.

In case that the first ink is supplied as described above, the first ink may be supplied by the nozzles 1111 arranged on only the first row of the first head part 1110. For example, the nozzles 1111 arranged on the second row of the first head part 1110 may not supply the first ink.

Thus, because the first ink is not supplied to the first openings OP1 through the nozzles 1111 arranged on the second row not used to supply the first ink, the first scatterers respectively included in the first quantum dot layers 561 arranged in the first opening OP1 may be prevented from having different concentrations. Moreover, because the concentrations of the first scatterers respectively included in the first quantum dot layers 561 are constant as described above, visual recognition of wrinkles or stains on the display apparatus 1 (e.g., refer to FIG. 1) may be reduced.

The above-described processes may also be similarly performed on the second quantum dot layers 563 (e.g., refer to FIG. 8C or 8E) and the light-transmissive layers 565 (e.g., refer to FIG. 8C or 8E) in addition to the first quantum dot layers 561 (e.g., refer to FIG. 8C or 8E).

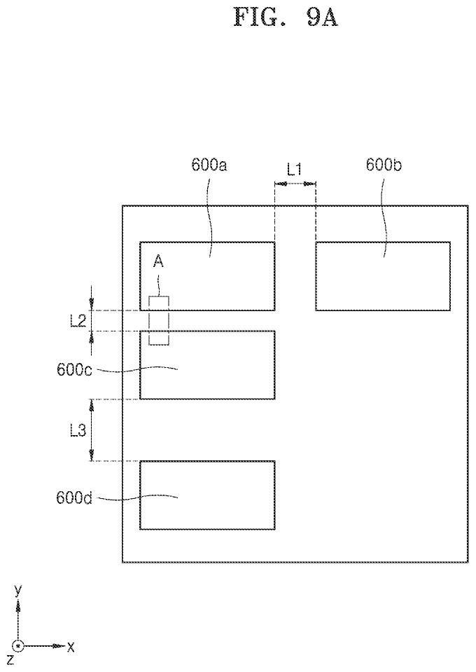

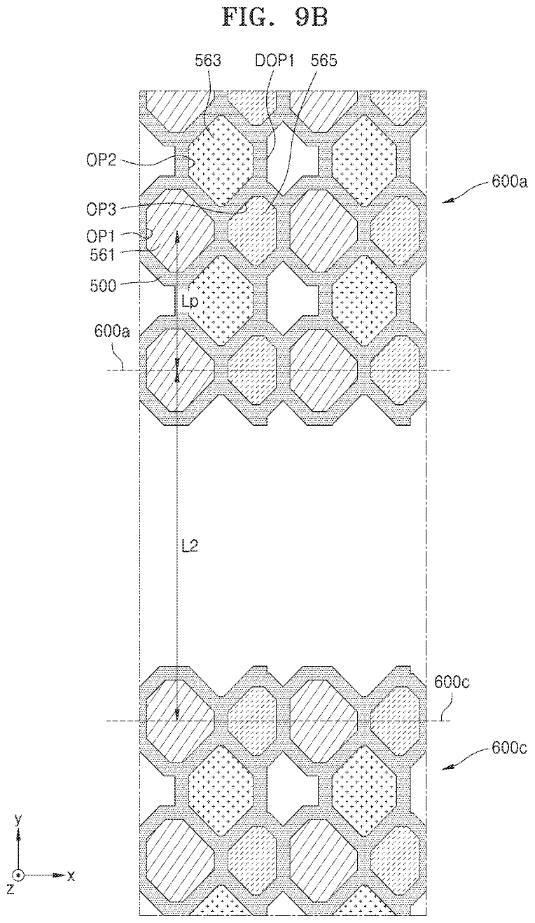

FIGS. 9A and 9B are schematic plan views of a color panel of a display apparatus according to an embodiment. FIG. 9B may be an enlarged view of area A in FIG. 9A.

Referring to FIGS. 9A and 9B, an upper substrate 600 (e.g., refer to FIG. 7) may include multiple coating regions 600a, 600b, 600c, 600d, and 600e (e.g., refer to FIG. 8F). A bank 500 (e.g., refer to FIG. 8C) including a first openings OP1, a second openings OP2, a third openings OP3, and a first dummy openings DOP1 may be arranged on the coating regions 600a, 600b, 600c, 600d, and 600e.

The coating regions 600a, 600b, 600c, 600d, and 600e may be arranged (or spaced) apart from one another in at least one of a first direction (e.g., x direction) and a second direction (e.g., y direction). A distance between every two adjacent coating regions among the coating regions 600a, 600b, 600c, 600d, and 600e may be a multiple of 1 or more of the distance Lp between adjacent ones of first quantum dot layers 561 arranged in adjacent first opening OP1 arranged on one coating region 600a, 600b, 600c, 600d, or 600e. Here, a multiple of 1 or more may refer to a multiple of a natural number of 1 or more, similar to this hereinafter.

For example, the coating regions 600a, 600b, 600c, 600d, and 600e may include a first coating region 600a and a second coating region 600b spaced apart from each other in the first direction (e.g., x direction). The coating regions 600a, 600b, 600c, 600d, and 600e may also include a third coating region 600c and a fourth coating region 600d spaced apart from the first coating region 600a in the second direction (e.g., y direction).

The first to fourth coating regions 600a, 600b, 600c, and 600d may have a same planar shapes. However, a first distance L1 between the first coating region 600a and the second coating region 600b, a second distance L2 between the first coating region 600a and the third coating region 600c, and a third distance L3 between the third coating region 600c and the fourth coating region 600d may be the same as one another or different from one another. For example, the first distance L1, the second distance L2, and the third distance L3 may be all the same as one another. According to another embodiment, one of the first distance L1, the second distance L2, and the third distance L3 may be different from another of the first distance L1, the second distance L2, and the third distance L3.

Each of the first distance L1, the second distance L2, and the third distance L3 may be a multiple of 1 or more of the distance Lp between adjacent ones of the first quantum dot layers 561 arranged in two adjacent first openings OP1. According to another embodiment, each of the first distance L1, the second distance L2, and the third distance L3 may be a multiple of 1 or more of a distance between adjacent ones of the second quantum dot layers 563 arranged in two adjacent second openings OP2. According to another embodiment, each of the first distance L1, the second distance L2, and the third distance L3 may be a multiple of 1 or more of a distance between adjacent ones of the light-transmissive layers 565 arranged in two adjacent third openings OP3. For convenience of explanation, a color panel of a display apparatus, in which each of the first distance L1, the second distance L2, and the third distance L3 is a multiple of 1 or more of the distance Lp between the adjacent ones of the first quantum dot layers 561 arranged in two adjacent first openings OP1, is described below.

The first coating region 600a may be defined by at least one of an outermost first opening OP1, an outermost second opening OP2, and an outermost third opening OP3. For example, the first coating region 600a may be a contour formed by at least one of outmost first openings OP1, outmost second openings OP2, and outmost third openings OP3. According to another embodiment, as shown in FIG. 9B, the first coating region 600a may be defined by a straight line that connects centers of openings arranged on a same column of the first openings OP1, the second openings OP2, and the third openings OP3.

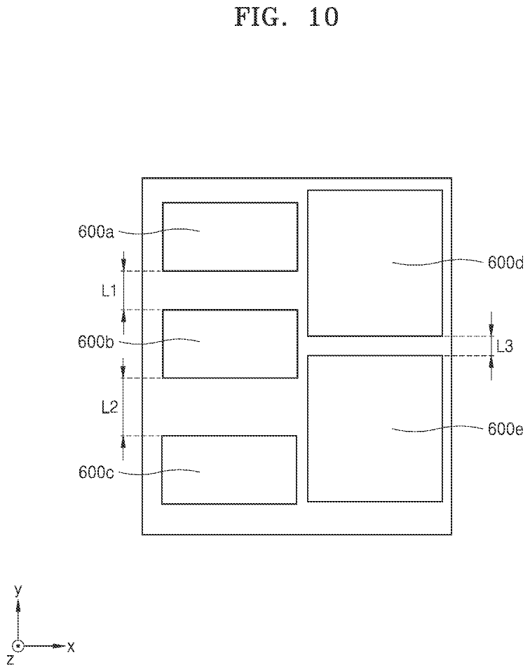

FIG. 10 is a schematic plan view of a color panel of a display apparatus according to an embodiment.

Referring to FIG. 10, an upper substrate 600 may include multiple coating regions 600a, 600b, 600c, 600d, and 600e. A planar shape of one of the coating regions 600a, 600b, 600c, 600d, and 600e may be different from that of another of the coating regions 600a, 600b, 600c, 600d, and 600e. A size of the planar shape of one of the coating regions 600a, 600b, 600c, 600d, and 600e may be different from that of the planar shape of the other of the coating regions 600a, 600b, 600c, 600d, and 600e.

The coating regions 600a, 600b, 600c, 600d, and 600e may include the first coating region 600a, the second coating region 600b, and the third coating region 600c spaced apart from one another in a second direction (e.g., y direction). The coating regions 600a, 600b, 600c, 600d, and 600e may also include a fourth coating region 600d and the fifth coating region 600e. The fourth coating region 600d may be spaced apart from the first coating region 600a in a first direction (e.g., x direction), and the fifth coating region 600e may be spaced apart from the fourth coating region 600d in the second direction. A planar shape of one (e.g., first to third coating regions 600a, 600b, and 600c) of the first to fifth coating regions 600a, 600b, 600c, 600d, and 600e may be different from those of the remaining coating regions (e.g., fourth and fifth coating regions 600d and 600e) of the first to fifth coating regions 600a, 600b, 600c, 600d, and 600e. For example, a size of a planar shape of the first coating region 600a may be less than that of a planar shape of the fourth coating region 600d. The first coating region 600a, the second coating region 600b, and the third coating region 600c may have a same planar shape. The fourth coating region 600d and the fifth coating region 600e may have a same planar shape and a same size.

The first to third coating regions 600a, 600b, and 600c arranged in the second direction (e.g., y direction) may be spaced apart from one another by a same distance or different distances. For example, a first distance L1 between the first coating region 600a and the second coating region 600b may be the same as or different from a second distance L2 between the second coating region 600b and the third coating region 600c. For example, in case that the first distance L1 and the second distance L2 are different from each other, one of the first distance L1 and the second distance L2 may be greater than another of the first distance L1 and the second distance L2.

A third distance L3 between the fourth coating region 600d and the fifth coating region 600e arranged in the second direction (e.g., y direction) may be the same as or different from at least one of the first distance L1 and the second distance L2.

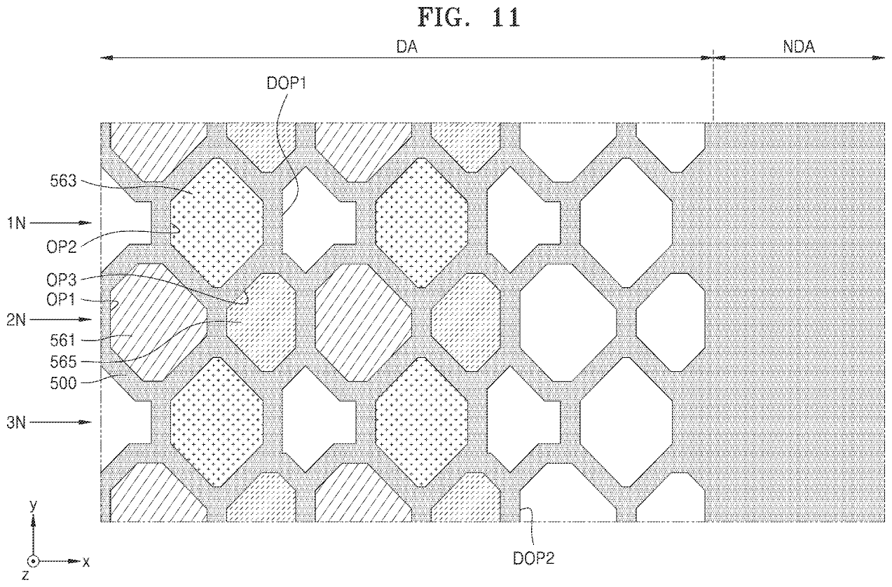

Each of the first distance L1, the second distance L2, and the third distance L3 may be a multiple of 1 or more of the distance Lp (e.g., refer to FIG. 11) between the adjacent ones of the first quantum dot layers 561 (e.g., refer to FIG. 11) arranged in two adjacent first openings OP1 (e.g., refer to FIG. 11).

Although not shown in the drawings, a distance between the first coating region 600a and the fourth coating region 600d adjacent to each other, a distance between the second coating region 600b and the fourth coating region 600d adjacent to each other, a distance between the second coating region 600b and the fifth coating region 600e adjacent to each other, and a distance between the third coating region 600c and the fifth coating region 600e adjacent to each other, which are measured in the first direction (e.g., x direction), may be a multiple of 1 or more of the distance Lp (e.g., refer to FIG. 11) between adjacent ones of the first quantum dot layers 561 (e.g., refer to FIG. 11) arranged in two adjacent first openings OP1 (e.g., refer to FIG. 11).

According to another embodiment, each of the four distances may be a multiple of 1 or more of a distance between adjacent ones of the second quantum dot layers 563 (e.g., refer to FIG. 11) arranged in two adjacent second openings OP2 (e.g., refer to FIG. 11). According to another embodiment, each of the four distances may be a multiple of 1 or more of a distance between adjacent ones of the light-transmissive layers 565 (e.g., refer to FIG. 11) arranged in two adjacent third openings OP3 (e.g., refer to FIG. 11). For convenience of explanation, a color panel 20 (e.g., refer to FIG. 2) of a display apparatus, in which each of the four distances is a multiple of 1 or more of the distance Lp (e.g., refer to FIG. 11) between the adjacent ones of the first quantum dot layers 561 (e.g., refer to FIG. 11) arranged in two adjacent first openings OP1 (e.g., refer to FIG. 11), is described below.

FIG. 11 is a schematic plan view of a color panel of a display apparatus according to an embodiment.

Referring to FIG. 11, a second dummy opening DOP2 may be arranged in a display area DA adjacent to a non-display area NDA. For example, the second dummy opening DOP2 may be defined in the bank 500 in the display area DA adjacent to the non-display area NDA. Thus, image quality uniformity and display quality of the display apparatus 1 (e.g., refer to FIG. 1) may be improved.

Although not shown in the drawings, dummy layers including the same material as one of the first quantum dot layer 561, the second quantum dot layer 563, and the light-transmissive layer 565 may be arranged within the second dummy opening DOP2 defined in the bank 500.

A method of forming the first quantum dot layer 561, the second quantum dot layer 563, the light-transmissive layer 565, and the dummy layers by moving nozzles may be the same as or similar to the method described above. For example, the movement of the nozzles in the method of forming the first quantum dot layer 561, the second quantum dot layer 563, the light-transmissive layer 565, and the dummy layers may be the same as or similar to the method described above with reference to FIGS. 8A to 8F. The nozzles may move (or be transported) by the same distance as or similar distance to the distance described above.

Apparatuses and methods for manufacturing a display apparatus, according to embodiments of the disclosure may prevent generation of stains on a display area of the display apparatus.

In apparatuses and methods for manufacturing a display apparatus, according to embodiments of the disclosure, a display apparatus displaying a precise image may be manufactured.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. An apparatus for manufacturing a display apparatus, the apparatus comprising:
a stage on which a substrate is disposed;
a first driver that moves the stage in a first direction;
a second driver connected to the first driver and moving the first driver in a second direction; and
a discharge part facing the stage and supplying droplets to the substrate,
wherein the second driver moves the stage by a multiple of a natural number of 1 or more of a distance between pixels arranged on the substrate.

2. The apparatus of claim 1, wherein
the second driver moves the substrate in the second direction such that the discharge part faces different regions of the substrate.

3. The apparatus of claim 1, wherein
the substrate comprises a plurality of coating regions,
a distance between the plurality of coating regions is a multiple of a natural number of 1 or more of the distance between the pixels arranged on the substrate,
at least one of the first driver and the second driver moves the stage by the distance between the plurality of coating regions so as to make the discharge part correspond to adjacent ones of the plurality of coating regions.

4. The apparatus of claim 3, wherein
the plurality of coating regions are spaced apart from one another in the first direction and the second direction, and
a first distance between the plurality of coating regions spaced apart from each other in the first direction and a second distance between the plurality of coating regions spaced apart from each other in the second direction are each multiples of a natural number of 1 or more of the distance between the pixels arranged on the substrate.

5. The apparatus of claim 1, wherein the droplets comprise quantum dots.

6. The apparatus of claim 5, wherein the droplets comprise a scatterer.

7. The apparatus of claim 5, wherein the droplets comprise titanium oxide.

8. A method of manufacturing a display apparatus, the method comprising:
moving a substrate in a first direction, and supplying droplets onto the substrate by a discharge part;
moving the substrate in a second direction; and
moving the substrate in an opposite direction to the first direction, and supplying the droplets onto the substrate by the discharge part,
wherein a distance by which the substrate moves in the second direction is a multiple of a natural number of 1 or more of a distance between pixels arranged on the substrate.

9. The method of claim 8, wherein the distance between the pixels of the substrate is a distance between pixels that emit light of a same color and are adjacent to each other.

10. The method of claim 8, wherein the droplets comprise quantum dots.

11. The method of claim 10, wherein the droplets comprise a scatterer.

12. The method of claim 10, wherein the droplets comprise titanium oxide.

13. The method of claim 8, further comprising:
forming a color filter layer on the substrate.

14. The method of claim 8, further comprising:
forming a thin-film encapsulation layer on the substrate.

15. The method of claim 8, further comprising:
arranging the substrate on a light-emitting panel.

16. The method of claim 8, wherein
the substrate comprises a plurality of coating regions, and
a distance between the plurality of coating regions is a multiple of a natural number of 1 or more of the distance between the pixels arranged on the substrate.

17. The method of claim 16, further comprising:
moving the substrate by the multiple of the natural number of 1 or more of the distance between the pixels arranged on the substrate in the first direction, such that the discharge part corresponds to one of the plurality of coating regions and another of the plurality of coating regions adjacent to the one of the plurality of coating regions in the first direction.

18. The method of claim 16, further comprising:
moving the substrate by the multiple of the natural number of 1 or more of the distance between the pixels arranged on the substrate in the second direction, such that the discharge part corresponds to one of the plurality of coating regions and another of the plurality of coating regions adjacent to the one of the plurality of coating regions in the second direction.

19. The method of claim 16, wherein a size of a planar shape of one of the plurality of coating regions is different from a size of a planar shape of another of the plurality of coating regions.

20. The method of claim 8, wherein
the discharge part comprises a plurality of nozzles, and
in case that the droplets are supplied to an entire surface of the substrate, only some of the plurality of nozzles continuously discharge the droplets.
